(19) United States
(12) Patent Application Publication
(10) Pub. No.: US 2017/0040208 A1
(43) Pub. Date: Feb. 9, 2017

(54) METHOD OF FORMING A PLUG, METHOD OF MANUFACTURING A SEMICONDUCTOR DEVICE USING THE SAME, POLISHING CHAMBER USED FOR MANUFACTURING THE SEMICONDUCTOR DEVICE, AND SEMICONDUCTOR DEVICE

(71) Applicant: SAMSUNG ELECTRONICS CO., LTD., Suwon-si (KR)

(72) Inventors: Seung-Hoon CHOI, Yongin-si (KR); Ho-Young KIM, Seongnam-si (KR); Gi-Gwan PARK, Suwon-si (KR); Hyun-Kyung BAE, Seoul (KR); Bo-Un YOON, Seoul (KR); Il-Young YOON, Hwaseong-si (KR)

(21) Appl. No.: 15/142,043

(22) Filed: Apr. 29, 2016

(30) Foreign Application Priority Data
Aug. 6, 2015 (KR) 10-2015-0111094

(51) Int. Cl. H01L 21/768

(52) U.S. Cl. CPC H01L 21/7684; H01L 21/76802; H01L 21/76865; H01L 21/76888

(57) ABSTRACT

A method of forming a plug and manufacturing a semiconductor device, a polishing chamber, and a semiconductor device, the method of forming a plug including forming an opening in an insulating interlayer pattern on a substrate; forming a metal layer to fill the opening; performing a first CMP process during a first time period until a top surface of the insulating interlayer pattern is exposed while pressing the substrate onto a first polishing pad to polish the metal layer; performing a second CMP process during a second time period while pressing the substrate onto a second polishing pad to polish the metal layer and the insulating interlayer pattern, so that a metal plug is formed in the insulating interlayer pattern; and performing a first cleaning process on the second polishing pad while keeping the substrate spaced apart from the second polishing pad on the second platen.

### CROSS-REFERENCE TO RELATED APPLICATION

Korean Patent Application No. 10-2015-0111094, filed on Aug. 6, 2015, in the Korean Intellectual Property Office, and entitled: “Method of Forming A Plug, Method of Manufacturing A Semiconductor Device Using the Same, Polishing Chamber Used for Manufacturing the Semiconductor Device, and Semiconductor Device,” is incorporated by reference herein in its entirety.

### BACKGROUND

1. Field

Embodiments relate to a method of forming a plug, a method of manufacturing a semiconductor device using the same, a polishing chamber used for manufacturing the semiconductor device, and a semiconductor device.

2. Description of the Related Art

When a tungsten contact plug is formed, an opening may be formed in an insulating interlayer on a wafer, a tungsten layer may fill the opening, and a CMP process may be performed to planarize the tungsten layer and the insulating interlayer.

### SUMMARY

Embodiments are directed to a method of forming a plug, a method of manufacturing a semiconductor device using the same, a polishing chamber used for manufacturing the semiconductor device, and a semiconductor device.

The embodiments may be realized by providing a method of forming a plug, the method including forming an opening in an insulating interlayer pattern on a substrate; forming a metal layer on the insulating interlayer pattern to fill the opening; performing a first CMP process during a first time period until a top surface of the insulating interlayer pattern is exposed while pressing the substrate onto a first polishing pad on a first platen to polish the metal layer; performing a second CMP process during a second time period that is shorter than the first time period while pressing the substrate onto a second polishing pad on a second platen to polish the metal layer and the insulating interlayer pattern, so that a metal plug is formed in the insulating interlayer pattern; and performing a first cleaning process on the second polishing pad while keeping the substrate spaced apart from the second polishing pad on the second platen.

The metal layer may be formed of tungsten, copper, or aluminum.

The metal layer may be formed of tungsten.

The first cleaning process performed on the second polishing pad may include providing deionized water on the second polishing pad.

The first cleaning process performed on the second polishing pad may be performed during a third time period, and a sum of a length of the second time period and a length of the third time period may be substantially equal to a length of the first time period.

Each of the first and second CMP processes may be performed using a slurry that includes abrasive particles and a strong acid solution.

The abrasive particles may include silica, alumina, or ceria.

The strong acid solution may include hydrogen peroxide.

During each of the first and second CMP processes, a metal oxide layer may be formed on the metal layer due to the strong acid solution.

The method may further include, after performing the first CMP process, cleaning the first polishing pad while keeping the substrate spaced apart from the first polishing pad on the first platen.

Cleaning the first polishing pad may include providing deionized water on the first polishing pad.

Cleaning the first polishing pad may be performed during a fourth time period, and the method further includes, after performing the first cleaning process on the second polishing pad, performing a second cleaning process on the second polishing pad during the fourth time period while keeping the substrate spaced apart from the second polishing pad on the second platen.

The plug has a positive potential with respect to the substrate.

The method further includes, prior to forming the metal layer on the insulating interlayer pattern, forming a barrier layer on an inner wall of the opening and the insulating interlayer pattern, wherein: the metal layer and the barrier layer are polished by the first CMP process, and the metal layer, the barrier layer, and the insulating interlayer pattern are polished by the second CMP process.

The barrier layer is formed of a metal nitride.

The method further includes, prior to forming the opening in the insulating interlayer pattern: forming an insulating interlayer on the substrate; and performing a third CMP process while pressing the substrate onto a third polishing pad on a third platen to polish the insulating interlayer, so that the insulating interlayer pattern is formed from the insulating interlayer.

The third CMP process is performed using a slurry including abrasive particles and an alkali solution.

The method further includes, prior to forming the insulating interlayer on the substrate, forming a resist pattern on the substrate, wherein a distance between the substrate and an outer surface of a portion of the insulating interlayer on the resist pattern is greater than a distance between the substrate and outer surfaces of other portions of the insulating interlayer.

The metal plug is formed such that the metal plug contacts the resist pattern.

The first CMP process, the second CMP process, and the third CMP process are performed in a same chamber.

The first CMP process and the second CMP process are performed in a same chamber including the first and second platens therein.

The embodiments may be realized by providing a method of forming a plug, the method including forming an opening in an insulating interlayer pattern on a substrate; forming a metal layer on the insulating interlayer pattern such that the metal layer fills the opening; performing a first CMP process while pressing the substrate onto a first polishing pad on a first platen to first polish the metal layer; cleaning the first polishing pad while keeping the substrate spaced apart from the first polishing pad on the first platen; performing a second CMP process while pressing the substrate onto a second polishing pad on a second platen until a top surface of the insulating interlayer pattern is exposed to second polish the metal layer; cleaning the second polishing pad while keeping the substrate spaced apart from the second polishing pad on the second platen; performing a third CMP process while pressing the substrate onto a third polishing pad on a third platen to polish the metal layer and the insulating interlayer pattern, so that a metal plug is formed in the insulating interlayer pattern; and cleaning the third polishing pad while keeping the substrate spaced apart from the third polishing pad on the third platen.

The first CMP process, the second CMP process, and the third CMP process are performed during substantially the same time.

The method further includes, prior to forming the opening in the insulating interlayer pattern: forming a resist pattern on the substrate; forming an insulating interlayer on the substrate to cover the resist pattern such that a distance between the substrate and an outer surface of a portion of the insulating interlayer on the resist pattern is greater than a distance between the substrate and outer surfaces of other portions of the insulating interlayer; and performing a fourth CMP process while pressing the substrate onto a fourth polishing pad on a fourth platen to polish the insulating interlayer such that the insulating interlayer pattern is formed from the insulating interlayer.

The first CMP process, the second CMP process, the third CMP process, and the fourth CMP process are performed in a same chamber including the first to fourth platens therein.

The first CMP process, the second CMP process, and the third CMP process are performed in a same chamber including the first to third platens therein.

The embodiments may be realized by providing a method of manufacturing a semiconductor device, the method including forming a transistor on a substrate; forming a first insulating interlayer on the substrate to cover the transistor; forming a first plug through the first insulating interlayer to be electrically connected to the transistor; forming a second insulating interlayer pattern on the first insulating interlayer and the first plug; forming a first opening through the second insulating interlayer pattern to expose a top surface of the first plug; forming a first metal layer on the second insulating interlayer pattern to fill the first opening; performing a first CMP process during a first time period until a top surface of the second insulating interlayer pattern is exposed while pressing the substrate onto a first polishing pad on a first platen to polish the first metal layer; performing a second CMP process during a second time period that is shorter than the first time period while pressing the substrate onto a second polishing pad on a second platen to polish the metal layer and the second insulating interlayer pattern, so that a second plug is formed in the second insulating interlayer pattern; and cleaning the second polishing pad while keeping the substrate spaced apart from the second polishing pad on the second platen.

The first metal layer is formed of tungsten.

Forming the first plug through the first insulating interlayer includes forming a second opening through the first insulating interlayer to expose a top surface of the substrate; forming a second metal layer on the substrate and the first insulating interlayer to fill the second opening; performing a third CMP process during a third time period until a top surface of the first insulating interlayer is exposed while pressing the substrate onto the first polishing pad on the first platen to polish the second metal layer; performing a fourth CMP process during a fourth time period that is shorter than the first time period while pressing the substrate onto the second polishing pad on the second platen to polish the second metal layer and the first insulating interlayer such that the first plug is formed in the first insulating interlayer; and cleaning the second polishing pad while keeping the substrate spaced apart from the second polishing pad on the second platen.

The second metal layer is formed of tungsten.

The method further includes, prior to forming the first opening in the second insulating interlayer pattern forming a resist pattern on the first insulating interlayer; forming a second insulating interlayer on the first insulating interlayer to cover the resist pattern; and performing a fifth CMP process while pressing the substrate onto a third polishing pad on a third platen to polish the second insulating interlayer, such that the second insulating interlayer pattern is formed from the second insulating interlayer.

The first opening is formed to expose a top surface of the resist pattern, and the second plug is formed to contact the resist pattern.

The method further includes, after forming the second plug in the second insulating interlayer pattern forming a third insulating interlayer on the second insulating interlayer pattern and the second plug; forming a third opening through the third insulating interlayer to expose a top surface of the second plug; forming a third metal layer on the exposed top surface of the second plug and the third insulating interlayer to fill the third opening; performing a fifth CMP process during a fifth time period until a top surface of the third insulating interlayer is exposed while pressing the substrate onto the first polishing pad on the first platen to polish the third metal layer; performing a sixth CMP process during a sixth time period that is shorter than the fifth time period while pressing the substrate onto the second polishing pad on the second platen to polish the third metal layer and the third insulating interlayer, so that a wiring is formed in the third insulating interlayer; and cleaning the second polishing pad while keeping the substrate spaced apart from the second polishing pad on the second platen.

The third metal layer is formed of copper.

The embodiments may be realized by providing a method of manufacturing a semiconductor device on each of a plurality of substrates using a polishing chamber including a plurality of platens having polishing pads, respectively, the method including performing a first CMP process until a top surface of a first insulating interlayer pattern on a first substrate is exposed while pressing the first substrate onto a first polishing pad on a first platen to polish a metal layer on the first insulating interlayer pattern, performing a second CMP process while pressing a second substrate onto a second polishing pad on a second platen to polish a second metal layer and a second insulating interlayer pattern on the second substrate, the second metal layer being in the second insulating interlayer pattern; and performing a first cleaning process on the second polishing pad while keeping the second substrate spaced apart from the second polishing pad.

The first CMP process and the second CMP process are performed during a first time period and a second time period, respectively, and the first cleaning process performed on the second polishing pad is performed during a third time period, and a length of the first time period is substantially equal to a sum of lengths of the second time period and the third time period.

The method further includes, after polishing the first metal layer on the first insulating interlayer pattern performing a cleaning process on the first polishing pad while keeping the first substrate spaced apart from the first polishing pad; and after performing the first cleaning process on the second polishing pad, performing a second cleaning process on the second polishing pad while keeping the second substrate spaced apart from the second polishing pad, wherein performing the cleaning process on the first polishing pad and performing a the second cleaning process on the second polishing pad are simultaneously performed during substantially the same time.

The first metal layer is also formed in the first insulating interlayer pattern, and the method further includes, after polishing the first metal layer on the first insulating interlayer pattern: performing a third CMP process while pressing the first substrate onto the second polishing pad to polish the first metal layer in the first insulating interlayer pattern on the first substrate and the first insulating interlayer pattern; and performing a third cleaning process on the second polishing pad while keeping the first substrate spaced apart from the second polishing pad.

The method further includes, during performing the third CMP process and third cleaning the second polishing pad, performing a fourth CMP process until a top surface of a third insulating interlayer pattern on a third substrate is exposed while pressing the third substrate onto the first polishing pad to polish a third metal layer on the third insulating interlayer pattern.

The method further includes, prior to polishing the second metal layer in the second insulating interlayer pattern and the second insulating interlayer pattern on the second substrate, performing a fifth CMP process until a top surface of the second insulating interlayer pattern on the second substrate is exposed while pressing the second substrate onto the first polishing pad to polish the second metal layer on the second insulating interlayer pattern.

The method further includes, prior to polishing the first metal layer on the first insulating interlayer pattern, performing a sixth CMP process while pressing the first substrate having the first insulating interlayer thereon onto a third polishing pad on a third platen to polish the first insulating interlayer, so that the first insulating interlayer pattern is formed from the first insulating interlayer.

The embodiments may be realized by providing a polishing chamber including a movement apparatus having a rotational axis and a plurality of rotating arms, the rotating arms being rotated by the rotational axis; a plurality of polishing heads under the rotating arms, respectively, each of the polishing pads moving by rotation of the rotating arms and being capable of rotating or moving in a line with a wafer on a bottom thereof; and a plurality of platens having a plurality of polishing pads thereon, respectively, wherein, during performing a first CMP process until a top surface of a first insulating interlayer pattern on a first wafer is exposed while a first polishing head of the plurality of polishing heads presses the first wafer held by the first polishing head onto a first polishing pad of the plurality of polishing heads to polish a metal layer on the first insulating interlayer pattern: a second CMP process is performed while a second polishing head of the plurality of polishing heads presses a second wafer held by the second polishing head onto a second polishing pad of the plurality of polishing pads to polish a second metal layer and a second insulating interlayer pattern on the second wafer, the second metal layer being in the second insulating interlayer pattern, and the second polishing pad undergoes a first cleaning process while the second wafer is spaced apart from the second polishing pad by the second polishing head.

The polishing chamber further includes a first slurry supply arm to provide a first slurry onto the first polishing pad during the first CMP process, the first slurry including abrasive particles and a strong acid solution; and a second slurry supply arm to provide a second slurry onto the second polishing pad during the second CMP process, the second slurry including abrasive particles and a strong acid solution.

When the first cleaning process is performed on the second polishing pad, the second slurry supply arm provides deionized water onto the second polishing pad.

After the first metal layer on the first insulating interlayer pattern is polished, the first polishing pad is cleaned while the first wafer is spaced apart from the first polishing pad by the first polishing head, after the second polishing pad is subjected to the first cleaning process, the second polishing pad is subjected to a second cleaning process while the second wafer is spaced apart from the second polishing pad by the second polishing head, and cleaning the first polishing pad and second cleaning the second polishing pad are simultaneously performed during substantially the same time.

A third CMP process is performed while a third polishing head of the plurality of polishing heads presses a third wafer held by the third polishing head onto a third polishing pad of the plurality of polishing pads to polish a third insulating interlayer on the third wafer, so that a third insulating interlayer pattern is formed from the third insulating interlayer.

The plurality of rotating arms includes four rotating arms, the plurality of polishing heads includes four polishing heads, and the plurality of platens includes three platens.

The embodiments may be realized by providing a semiconductor device including first and second impurity regions in first and second regions of a substrate; a first insulating interlayer on the substrate; and first and second plugs through the first insulating interlayer, the first and second plugs being electrically connected to the first and second impurity regions, respectively, wherein a top surface of the first plug has a first height that is shorter than a second height of a top surface of the second plug, a difference between the first and second heights being equal to or less than about 20% of a length from a bottom of the second plug to the top surface of the second plug.

The first and second plugs directly contact top surfaces of the first and second impurity regions, respectively.

The first impurity region is doped with p-type impurities, and the second impurity region is doped with n-type impurities.

A bottom of the first contact plug is lower than that of the second contact plug.

The semiconductor device further includes a second insulating interlayer on the first insulating interlayer and the first and second plugs; and third and fourth plugs through the second insulating interlayer, the third and fourth plugs being electrically connected to the first and second plugs, respectively, and including metal, wherein a top surface of the third plug has a third height lower than a fourth height of a top surface of the fourth plug, the third height being equal to or more than about 80% of the fourth height.

The semiconductor device further includes a resist pattern on the first insulating interlayer, the resist pattern being covered by the second insulating interlayer.

The embodiments may be realized by providing a semiconductor device including first and second impurity regions in first and second regions of a substrate; a first insulating interlayer on the substrate; and a first plug extending through the first insulating layer and a second plug extending through the first insulating interlayer, the first plug being electrically connected to the first impurity region and the second plug being electrically connected to the second impurity region, wherein a first distance from the substrate to an outer surface of the first plug is smaller than a second distance from the substrate to an outer surface of the second plug, a difference between the first distance and second distance being equal to or less than about 20% of the second distance.

The first plug directly contacts a facing surface of the first impurity region, and the second plug directly contacts a facing surface of the second impurity region.

The first impurity region is doped with p-type impurities, and the second impurity region is doped with n-type impurities.

A substrate-facing side of the first contact plug is closer to the substrate than a substrate-facing side of the second contact plug.

The semiconductor device further includes a second insulating interlayer on the first insulating interlayer and the first and second plugs; and third and fourth plugs through the second insulating interlayer, the third and fourth plugs being electrically connected to the first and second plugs, respectively, and including metal, wherein an outer surface of the third plug is a third distance from the substrate, the third distance being smaller than a fourth distance of an outer surface of the fourth plug from the substrate, the third distance being equal to or more than about 80% of the fourth distance.

The semiconductor device further includes a resist pattern on the first insulating interlayer, the resist pattern being covered by the second insulating interlayer.

### BRIEF DESCRIPTION OF THE DRAWINGS

Features will be apparent to those of skill in the art by describing in detail exemplary embodiments with reference to the attached drawings in which:

FIG. 1 illustrates a plan view of a polishing chamber used for forming a plug in accordance with example embodiments, and FIG. 2 illustrates a perspective view of a region X of the polishing chamber;

FIG. 3 illustrates a flowchart of stages of a method of forming a plug in accordance with example embodiments, and FIGS. 4 to 11 illustrate cross-sectional views of the stages of the method of forming the plug;

FIG. 12 illustrates a flowchart of stages of a method of forming a plug in accordance with example embodiments, and FIGS. 13 to 17 illustrate cross-sectional views of the stages of the method of forming the plug;

FIG. 18 illustrates a plan view of a polishing chamber used for forming a plug in accordance with example embodiments;

FIG. 19 illustrates a flowchart of stages of a method of forming a plug in accordance with example embodiments;

FIG. 20 illustrates a cross-sectional view of plugs formed by the method of forming the plugs in accordance with example embodiments; and

FIGS. 21, 22A, 22B, 23 to 32, 33A, 33B, 34A, 34B, 35 to 41, 42A, 42B, 43A, 43B, 44A, 44B, 45A, 45B, 46 to 49, 50A, 50B, 51, 52A, 52B, 53A, and 53B illustrate plan views and cross-sectional views of stages of a method of manufacturing a semiconductor device in accordance with example embodiments.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. Like reference numerals refer to like elements throughout.

It will be understood that when an element or layer is referred to as being “on,” “between,” “connected to” or “coupled to” another element or layer, it can be directly on, between, connected or coupled to the other element or layer or intervening elements or layers may be present. In contrast, when an element is referred to as being “directly on,” “directly between,” “directly connected to” or “directly coupled to” another element or layer, there are no intervening elements or layers present. As used herein, the term “and/or” includes any and all combinations of one or more of the associated listed items.

It will be understood that, although the terms first, second, third, fourth etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present application.

Spatially relative terms, such as “beneath,” “below,” “under,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below,” “under” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

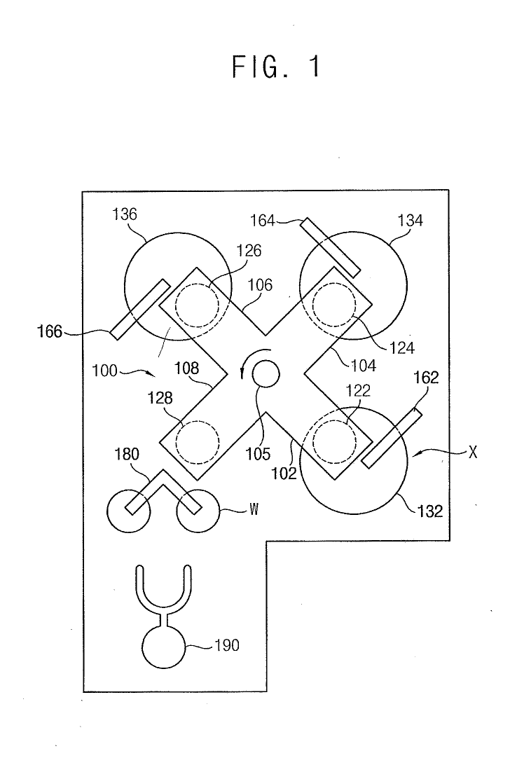

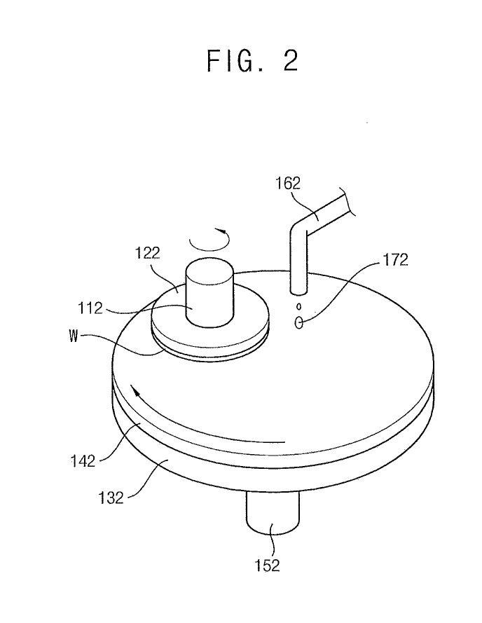

FIG. 1 illustrates a plan view of a polishing chamber used for forming a plug in accordance with example embodiments, and FIG. 2 illustrates a perspective view of a region X of the polishing chamber.

Referring to FIGS. 1 and 2, the polishing chamber may include, e.g., a movement apparatus 100, first to fourth polishing heads 122, 124, 126 and 128, first to third CMP units, a wafer exchange apparatus 180, and a transfer robot 190. The first to third CMP units may include first to third platens 132, 134 and 136, respectively.

The movement apparatus 100 may include a rotational axis 105, and first to fourth rotating arms 102, 104, 106 and 108 coupled to, e.g., under, the rotational axis 105, which may extend in a radial shape or direction.

In example embodiments, the first and third rotating arms 102 and 106 may extend in a first direction and a third direction (which may be opposite to the first direction) respectively, from the rotational axis 105. The second and fourth rotating arms 104 and 108 may extend in a second direction and a fourth direction (which may be opposite to the second direction) respectively, from the rotational axis 105. As the rotational axis 105 rotates, the first to fourth rotating arms 102, 104, 106 and 108 may also rotate.

Each of the first to fourth polishing heads 122, 124, 126 and 128 may hold a substrate thereunder, e.g., a wafer W on which a polishing target layer may be formed.

For example, the first polishing head 122 may move vertically by a first driving member 112 under the first rotating arm 102, and thus the wafer W may be put into contact an upper surface of a first polishing pad 142 on the first platen 132. For example, the first polishing head 122 may apply a pressure onto the wafer W or the first polishing pad 142. The first polishing head 122 may rotate or move in a line, e.g., straight line, by the first driving member 112 while the wafer W contacts the first polishing pad 142, and thus the wafer W held by the first polishing head 122 may also rotate or move in a line, e.g., straight line.

Like the first polishing head 122, the second to fourth polishing heads 124, 126 and 128 may move vertically by second to fourth driving members under the second to fourth rotating arms 104, 106 and 108, respectively, or may rotate and/or move in a line, e.g., straight line.

The first to fourth rotating arms 102, 104, 106, and 108 may rotate by rotation of the rotational axis 105, and relative positions between the first to fourth polishing heads 122, 124, 126 and 128 and the first to third platens 132, 134 and 136 may vary according to time. When the first to third polishing heads 122, 124 and 126 are disposed on the first to third platens 132, 134 and 136, respectively, at the end of a first time period, the first to fourth rotating arms 102, 104, 106 and 108 may then rotate, e.g., in a counterclockwise direction so that the fourth, the first and the second polishing heads 128, 122 and 124 may be disposed on the first, the second, and the third platens 132, 134 and 136, respectively, for a second time period.

The first CMP unit may include a first driving axis 152, the first platen 132, the first polishing pad 142, and a first slurry supply arm 162.

The first driving axis 152 may be disposed under the first platen 132 and rotate the first platen 132, and thus the first polishing pad 142 mounted on the first platen 132 may also rotate.

In example embodiments, each of the first platen 132 and the first polishing pad 142 may have a shape of a disc. The first polishing pad 142 may include grooves through which a first slurry 172 provided by the first slurry supply arm 162 may move, and micropores in which the first slurry 172 may be contained.

The first polishing pad 142 may be a hard pad or a soft pad, and may include, e.g., polyurethane. The first slurry 172 may include, e.g., abrasive particles and strong acid solution. The abrasive particles may include, e.g., silica, alumina, ceria, or the like, and the strong acid solution, which may have a pH equal to or less than about 2, may include, e.g., peroxide (such as hydrogen peroxide), hydrochloric acid, or the like.

The first slurry supply arm 162 may also provide a cleaning solution, e.g., deionized water (DIW), onto the first polishing pad 142 in addition to providing the first slurry 172.

When a CMP process is performed by the first CMP unit and the first polishing head 122, the polishing target layer on the wafer W may be mechanically polished by the rotation and/or the movement in a (straight) line of the wafer W held by the first polishing head 122, and may be chemically and/or mechanically polished by the first slurry 172 provided by the first slurry supply arm 162.

In an implementation, the first CMP unit may further include a first pad conditioner on the first polishing pad 142. The pad conditioner may move in a vertical direction by an additional driving member, and may contact an upper surface of the first polishing pad 142 to apply pressure thereonto. The pad conditioner may rotate or move in a line, e.g., straight line, by the driving member while the pad conditioner contacts the first polishing pad 142, and thus polishing residue or slurry residue remaining on the first polishing pad 142 may be removed, or the roughness of the first polishing pad 142 may be kept in an optimum state.

Like the first CMP unit, the second CMP unit may include a second driving axis, the second platen 134, a second polishing pad, and a second slurry supply arm 164.

The second slurry supply arm 164 may provide a second slurry including abrasive particles and strong acid solution, and a cleaning solution, e.g., deionized water (DIW), onto the second polishing pad.

Like the first CMP unit, the third CMP unit may include a third driving axis, the third platen 136, a third polishing pad, and a third slurry supply arm 166.

The third slurry supply arm 166 may provide a third slurry, e.g., including abrasive particles and alkali solution, and a cleaning solution, e.g., deionized water (DIW), onto the third polishing pad. The alkali solution may include, e.g., ammonium hydroxide.

The wafer transfer apparatus 180 may hold the wafer W thereunder, and may transfer the wafer W to the movement apparatus 100, or receive the wafer W from the movement apparatus 100. The transfer robot 190 may receive wafer W from an outside of the polishing chamber, e.g., a cleaning chamber, a deposition chamber, etc., and may transfer the wafer W to the wafer transfer apparatus 180 of the polishing chamber.

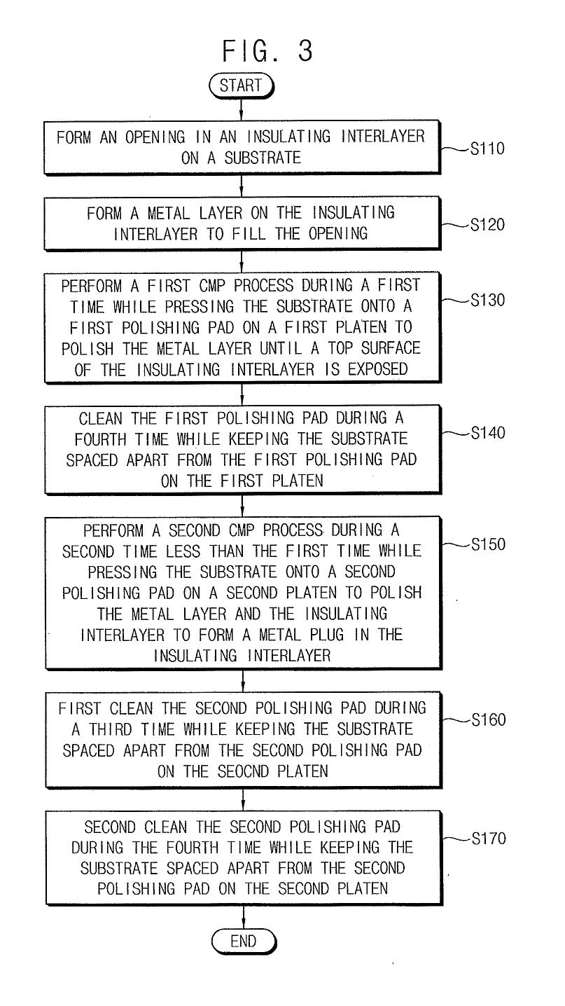

FIG. 3 illustrates a flowchart of stages of a method of forming a plug in accordance with example embodiments, and FIGS. 4 to 11 illustrate cross-sectional views of the stages of the method of forming the plug. The method of forming the plug may be performed using the polishing chamber illustrated with reference to FIGS. 1 and 2, and thus may be illustrated with reference to the polishing chamber when necessary.

Referring to FIGS. 3 and 4, in step S110, an insulating interlayer 210 may be formed on a substrate 200, and the insulating interlayer 210 may be partially removed to form an opening 220 exposing a top surface of the substrate 200.

The substrate 200 may include a semiconductor material, e.g., silicon, germanium, silicon-germanium, or III-V semiconductor compounds, (such as GaP, GaAs, GaSb, etc.). In an example embodiment, the substrate 200 may be a silicon-on-insulator (SOI) substrate or a germanium-on-insulator (GOI) substrate.

Various types of elements, e.g., a gate structure, a source/drain layer, etc. may be formed on the substrate 200, and may be covered by the insulating interlayer 210. Thus, in an implementation, the opening 220 may be formed to expose the elements instead of the top surface of the substrate 200.

The insulating interlayer 210 may include, e.g., silicon oxide. In an implementation, the insulating interlayer 210 may include a low-k dielectric material, e.g., silicon oxide doped with carbon (SiCOH) or silicon oxide doped with fluorine (F—SiO₂), a porous silicon oxide, spin on organic polymer, or an inorganic polymer, e.g., hydrogen silsesquioxane (HSSQ), methyl silsesquioxane (MSSQ), etc.

The opening 220 may be formed by forming a photoresist pattern on the insulating interlayer 210, and performing an etching process using the photoresist pattern as an etching mask. The opening 220 may be formed through the insulating interlayer 210.

Referring to FIGS. 3 and 5, in step S120, a barrier layer 230 may be formed on the exposed top surface of the substrate 200, a sidewall of the opening 220, and the insulating interlayer 210, and a metal layer 240 may be formed on the barrier layer 230 to fill a remaining portion of the opening 220.

The barrier layer 230 may be formed of a metal nitride, e.g., tantalum nitride, titanium nitride, etc., and/or a metal, e.g., tantalum, titanium, etc., and the metal layer 240 may be formed of a metal, e.g., tungsten, copper, aluminum, etc.

In example embodiments, the metal layer 240 may be formed to have a top or outer surface higher than that of the insulating interlayer 210 so as to sufficiently fill the opening 220. For example, the metal layer 240 may cover the insulating interlayer 210 and fill the opening 220.

Referring to FIGS. 3, 6 and 7, in step S130, a first CMP process may be performed during a first time period. The first CMP process may include pressing the substrate 200 (via the first polishing head 122) onto an upper surface (e.g., polishing surface) of the first polishing pad 142 mounted on the first platen 132.

In example embodiments, the first CMP process may be performed until a top surface (e.g., outer surface) of the insulating interlayer 210 is exposed. Thus, the barrier layer 230 and the metal layer 240 may be polished to form a preliminary barrier pattern 235 and a preliminary metal pattern 245, respectively.

The first polishing head 122 may press the substrate 200 onto the upper surface of the first polishing pad 142 by the first driving member 112 on the first polishing head 122, and may rotate according to the rotation of the first driving member 112 during the first CMP process. Accordingly, the substrate 200 held by the first polishing head 122 may contact the upper surface of the first polishing pad 142 and rotate.

During the first CMP process, the first slurry supply arm 162 may provide the first slurry 172 onto the upper surface of the first polishing pad 142. For example, when the metal layer 240 includes tungsten, a tungsten oxide (WOx) layer may be formed on the metal layer 240 by the strong acid solution included in the first slurry 172, e.g., hydrogen peroxide, and may be removed by the abrasive particles in the first slurry 172.

Referring to FIGS. 3 and 8, in step S140, the first polishing pad 142 may be cleaned during a fourth time period (that is much shorter than the first time period) and the substrate 200 may be maintained in a spaced apart relationship from the first polishing pad 142 on the first platen 132 via the first polishing head 122 as the first polishing pad 142 is cleaned.

In example embodiments, as the first driving member 112 moves upwardly above or away from the upper surface of the first polishing pad 142, the first polishing head 122 attached to the first driving member 112 and the substrate 200 held by the first polishing head 122 may be moved to be spaced apart from the upper surface of the first polishing pad 142.

The cleaning process may be performed on the first polishing pad 142 by providing a cleaning solution, e.g., deionized water (DIW), onto the upper surface (e.g., polishing surface) of the first polishing pad 142 via the first slurry supply arm 162. The substrate 200 (having the preliminary barrier pattern 235 and the preliminary metal pattern 245 thereon) may be spaced apart from the upper surface of the first polishing pad 142, and the preliminary barrier pattern 235 and the preliminary metal pattern 245 may not contact the DIW. Thus, the acidity of the tungsten oxide layer on the preliminary metal pattern 245 may not increase or change due to DIW, and may not be removed by remaining slurry residue and/or pad residue on the polishing surface of the first polishing pad 142.

If the cleaning process were to be performed while the substrate 200 was in contact with the polishing surface of the first polishing pad 142, the acidity of the first slurry 172 remaining on the first polishing pad 142 and the preliminary metal pattern 245 may increase or change due to the DIW, and thus the tungsten oxide layer could be transformed into an electrolyte layer of oxidized tungsten, e.g., WO₄²⁻, WO₅²⁻, etc. The electrolyte layer of oxidized tungsten may be easily removed, and thus the preliminary metal pattern 245 including tungsten may be directly exposed and be removed by the first polishing pad 142, which may form a recess.

In example embodiments, the cleaning process may be performed while the substrate 200 is spaced apart from the polishing surface of the first polishing pad 142, and thus the tungsten oxide layer may not be transformed or removed, and no recess may be formed in the preliminary metal pattern 245 including tungsten.

In an example embodiment, the first polishing pad 142 and/or the first polishing head 122 may not rotate and/or may not move in the cleaning process.

Referring to FIGS. 3,9 and 10, in step S150, a second CMP process may be performed during a second time period (e.g., which may be shorter than the first time period) while pressing the substrate 200 via the first polishing head 122 onto an upper surface (e.g., polishing surface) of the second polishing pad 144 that is mounted on the second platen 134.

In example embodiments, the second CMP process may be performed on the preliminary barrier pattern 235, the preliminary metal pattern 245, and the insulating interlayer 210, and thus a plug 257 (including a barrier pattern 237 and a metal pattern 247) may be formed in the insulating interlayer 210.

In example embodiments, the first rotating arm 102 may move from the first platen 132 to the second platen 134 by the rotation of the rotational axis 105, and thus the first driving member 112 coupled with (e.g., under) the first rotating arm 102 and the first polishing head 122 attached thereto may also move to the second platen 134.

The first polishing head 122 may press the substrate 200 via the first driving member 112 onto the polishing surface of the second polishing pad 144, and may also rotate according to the rotation of the first driving member 112 during the second CMP process. Thus, the substrate 200 held by the first polishing head 122 may contact the second polishing pad 144 on the second platen 134 and rotate.

During the second CMP process, the second slurry supply arm 164 may provide the second slurry 174 onto the upper surface of the second polishing pad 144. Thus, when the preliminary metal pattern 245 includes tungsten, a tungsten oxide (WOx) layer may be formed on the preliminary metal pattern 245 by a strong acid solution included in the second slurry 174, e.g., hydrogen peroxide, which may then be removed by abrasive particles in the second slurry 174.

Referring to FIGS. 3 and 11, in step S160, the second polishing pad 144 may be first cleaned by performing a first cleaning process during a third time period (that is much shorter than the first time period) as the substrate 200 is maintained in a spaced apart relationship relative to the second polishing pad 144 on the second platen 134 via the first polishing head 122.

In example embodiments, as the first driving member 112 moves upwardly above or away from the polishing surface of the second polishing pad 144, the first polishing head 122 (attached to the first driving member 112 and the substrate 200 held by the first polishing head 122) may be moved to be spaced apart from the polishing surface of the second polishing pad 144.

The first cleaning process may be performed on the second polishing pad 144 by providing a cleaning solution, e.g., DIW, onto the polishing surface of the second polishing pad 144 via the second slurry supply arm 164. The substrate 200 (having the barrier pattern 237 and the metal pattern 247 thereon) may be spaced apart from the polishing surface of the second polishing pad 144 during the cleaning process, and the barrier pattern 237 and the metal pattern 247 may not contact the DIW. Thus, the acidity of the tungsten oxide layer on the metal pattern 247 may not change or increase due to the DIW, and may not be removed by the remaining slurry residue and/or the pad residue on the polishing surface of the second polishing pad 144. Accordingly, no recess may be formed in the metal pattern 247 including tungsten.

In an example embodiment, the second polishing pad 144 and/or the first polishing head 122 may not rotate or may not move during the first cleaning process.

In example embodiments, a sum of the length of the second time period and the third time period may be substantially equal to the length of the first time period. For example, a length of time for performing the first CMP process on the substrate 200 may be substantially equal to a sum of a length of time for performing the second CMP process on the substrate 200 and a length of time for performing the first cleaning process on the second polishing pad 144.

In step S170, a second cleaning process (that is substantially the same as or similar to the cleaning process on the first polishing pad 142 illustrated with reference to step S140) may be performed on the second polishing pad 144.

For example, the second polishing pad 144 may be cleaned during the fourth time period (which may be much shorter than the first time period) while maintaining the substrate 200 in a spaced apart relationship relative to the second polishing pad 144 on the second platen 134 via the first polishing head 122.

At this time, the first cleaning process on the second polishing pad 144 has been finished, and thus the first polishing head 122 attached to the first driving member 112 and the substrate 200 held by the first polishing head 122 may be spaced apart from the upper surface of the second polishing pad 144. Thus, the second cleaning process may be substantially the same as an additional first cleaning process but is performed during the fourth time period.

By the above processes, e.g., by performing the CMP processes in the polishing chamber, the plug 257 including the barrier pattern 237 and the metal pattern 247 may be formed.

As described above, the first CMP process may be performed on the metal layer 240 that filled the opening 220 in the insulating interlayer 210, during the first time period, and on the first platen 132, the second CMP process may be performed on the metal layer 240 and the insulating interlayer 210, during the second time period (that is shorter than the first time period) and on the second platen 134, and the first cleaning process may be performed on the second polishing pad 144 on the second platen 134 during the third time period (that is shorter than the first time period). The first cleaning process may be performed while keeping the substrate 200 spaced apart from the polishing surface of the second polishing pad 144, and thus no recess may be formed in the metal pattern 247 during the first cleaning process. After the first CMP process and the first cleaning process, the second cleaning process may be further performed on the first and second polishing pads 142 and 144 disposed on the first and second platens 132 and 134, respectively, and the second cleaning process may be performed while the substrate 200 is spaced apart from polishing surfaces of the first and second polishing pads 142 and 144. Thus, no recess may be formed in the metal pattern 247.

Up to now, the method of forming the plug 257 on one substrate 200 has been described. In an implementation, a plurality of plugs may be formed on a plurality of substrates, respectively, in the polishing chamber.

For example, first and second substrates may be loaded onto the first and second polishing heads 122 and 124, respectively, by the first and second rotating arms 102 and 104, respectively.

A first CMP process may be performed on a first metal layer on a first insulating interlayer disposed on the first substrate until a top or outer surface of the first insulating interlayer is exposed while pressing the first substrate onto the first polishing pad 142.

During the first CMP process, a second CMP process may be performed on a second metal layer in a second insulating interlayer disposed on the second substrate and the insulating interlayer while pressing the second substrate onto the second polishing pad 144 on the second platen 134, and a first cleaning process may be performed on the second polishing pad 144 while keeping the second substrate spaced apart from the second polishing pad 144.

After the first CMP process, a cleaning process may be performed on the first polishing pad 142 on the first platen 132. After the second CMP process and the first cleaning process, a second cleaning process may be performed on the second polishing pad 144 on the second platen 134.

In an implementation, the CMP processes and the cleaning processes may be simultaneously performed on the first and second platens 132 and 134. After finishing the processes, e.g., the second substrate may be transferred to an outside by the second rotating arm 104, the first substrate may move toward the second platen 134 by the first rotating arm 102, and a third substrate may move from the outside toward the first platen 132 by the fourth rotating arm 108.

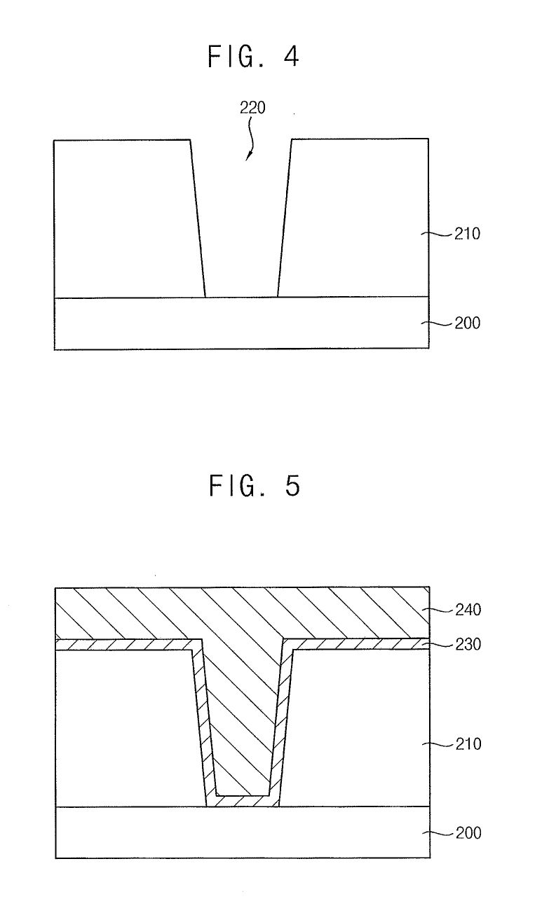

FIG. 12 illustrates a flowchart of stages of a method of forming a plug in accordance with example embodiments, and FIGS. 13 to 17 illustrate cross-sectional views of the stages of the method of forming the plug. The method of forming the plug may be performed using the polishing chamber illustrated in FIGS. 1 and 2, and thus may be illustrated with reference to the polishing chamber when necessary. Additionally, this method may include processes substantially the same as or similar to those described with reference to FIGS. 3 to 11, and repeated detailed descriptions thereon may be omitted herein.

Referring to FIGS. 12 and 13, in step S210, a resist pattern 305 may be formed on a substrate 300, and an insulating interlayer 310 may be formed on the substrate 300 to cover the resist pattern 305.

The resist pattern 305 may be formed of a metal, a metal silicide, doped polysilicon, or the like. In an example embodiment, the resist pattern 305 may be formed of tungsten silicide.

As the resist pattern 305 is formed on the substrate 300, a portion of the insulating interlayer 310 on the resist pattern 305 may have a top or outer surface that is higher than (e.g., further from the substrate 300) that of other portions of the insulating interlayer 310.

In an implementation, other elements, e.g., gate structures, source/drain layers, wirings, etc. may be formed on the substrate 300, and the insulating interlayer 310 may be formed on the substrate 300 to cover the elements.

Referring to FIGS. 12, 14, and 15, in step S220, a third CMP process may be performed during a fifth time period while pressing the substrate 300 (via the third polishing head 126) onto an upper or polishing surface of the third polishing pad 146 mounted on the third platen 136.

In example embodiments, the third CMP process may be performed on the insulating interlayer 310, and thus an insulating interlayer pattern 315 having a flat top surface may be formed.

The third polishing head 126 may press the substrate 300 onto the polishing surface of the third polishing pad 146 by the third driving member 116 on the third polishing head 126, and may rotate according to the rotation of the third driving member 116 during the third CMP process. Accordingly, the substrate 300 held by the third polishing head 126 may contact the upper surface of the third polishing pad 146 and rotate.

During the third CMP process, the third slurry supply arm 166 may provide the third slurry 176 onto the polishing surface of the third polishing pad 146. The third slurry 176 may include an alkali solution, e.g., ammonia, and abrasive particles.

Referring to FIGS. 12 and 16, in step S230, the third polishing pad 146 may be cleaned during a sixth time period (that is much shorter than the fifth time period) while keeping the substrate 300 spaced apart from the third polishing pad 146 on the third platen 136 via the third polishing head 126.

In example embodiments, as the third driving member 116 moves upwardly above or away from the polishing surface of the third polishing pad 146, the third polishing head 126 (attached to the third driving member 116) and the substrate 300 (held by the third polishing head 126) may be moved to be spaced apart from the polishing surface of the third polishing pad 146.

A cleaning process may be performed on the third polishing pad 146 by providing a cleaning solution, e.g., DIW, onto the polishing surface of the third polishing pad 146 via the third slurry supply arm 166.

In an implementation, the cleaning process may be performed while the substrate 300 contacts the third polishing pad 146 on the third platen 136.

Processes substantially the same as or similar to those described with reference to FIGS. 3 to 11 may then be performed to form first and second plugs 357 and 359 through the insulating interlayer pattern 315.

For example, the third rotating arm 106 may move away from the third platen 136 by the rotation of the rotational axis 105, and thus the substrate 300 held by the third polishing head 126 under or on the third rotating arm 106 may be transferred to an outside of the polishing chamber by the wafer exchange apparatus 180 and the transfer robot 190.

After the steps S110 and S120, the substrate 300 may be loaded onto the first polishing head 122 under or on the first rotating arm 102 of the movement apparatus 100 by the transfer robot 190 and the wafer exchange apparatus 180. The steps S130 to S170 may be performed to form the first and second plugs 357 and 359.

The first plug 357 may contact a top surface of the substrate 300, and the second plug 359 may contact a top surface of the resist pattern 305. The first plug 357 may include a first metal pattern 347 and a first barrier pattern 337 covering a bottom and a sidewall of the first metal pattern 347. The second plug 359 may include a second metal pattern 349 and a second barrier pattern 339 covering a bottom and a sidewall of the second metal pattern 349.

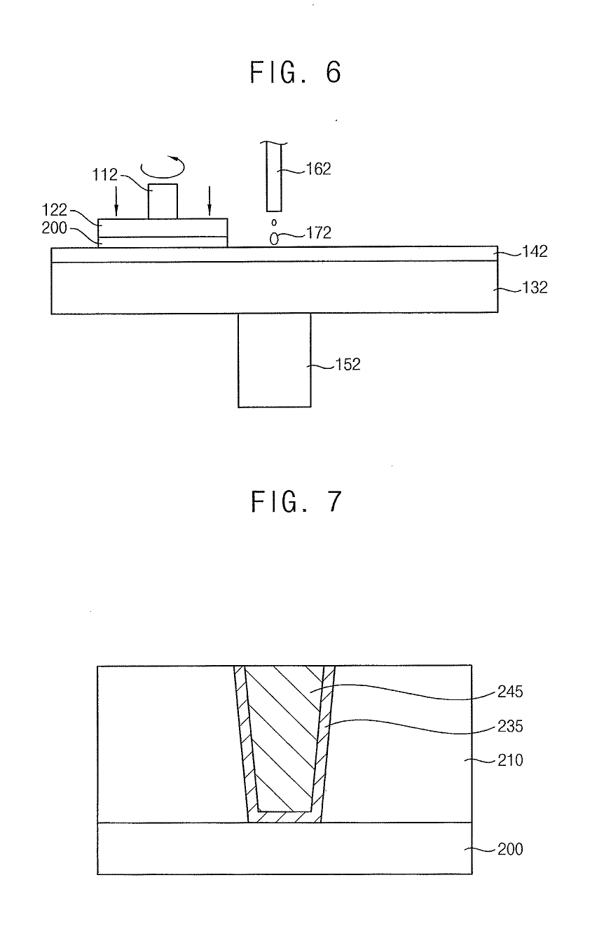

FIG. 18 illustrates a plan view of a polishing chamber used for forming a plug in accordance with example embodiments. This polishing chamber may be substantially the same as or similar to that illustrated in FIGS. 1 and 2, except for the numbers of the rotating arm, the polishing head, the platen, and the slurry supply arm. Thus, like reference numerals refer to like elements, and repeated detailed descriptions thereon may be omitted below in the interest of brevity.

Referring to FIG. 18, the polishing chamber may include the movement apparatus 100, the first to fourth polishing heads 122, 124, 126, and 128, a fifth polishing head 129, the first to third CMP units, a fourth CMP unit, the wafer exchange apparatus 180, and the transfer robot 190. The first to third CMP units may include the first to third platens 132, 134 and 136, respectively, and the fourth CMP unit may include a fourth platen 139.

The movement apparatus 100 may include the rotational axis 105, and the first to fourth rotating arms 102, 104, 106 and 108 and a fifth rotating arm 109 under the rotational axis 105, which may extend in a radial shape.

In example embodiments, the first to fifth rotating arms 102, 104, 106, 108 and 109 may extend from the rotational axis 105 toward vertices of a regular pentagon, respectively, and thus an angle of about 72 degrees may be formed between neighboring ones of the rotating arms 102, 104, 106, 108 and 109.

The first to fifth polishing heads 122, 124, 126, 128 and 129 may be disposed under the first to fifth rotating arms 102, 104, 106, 108 and 109, respectively, and first to fourth polishing may be mounted on the first to fourth platens 132, 134, 136 and 139, respectively.

The first to third CMP units may include the first to third slurry supply arms 162, 164 and 166, and the fourth CMP unit may include a fourth slurry supply arm 169. In example embodiments, the first to third slurry supply arms 162, 164 and 166 may provide the first to third slurries, respectively, each of which may include abrasive particles and a strong acid solution, and the fourth slurry supply arm 169 may provide a fourth slurry including abrasive particles and an alkali solution.

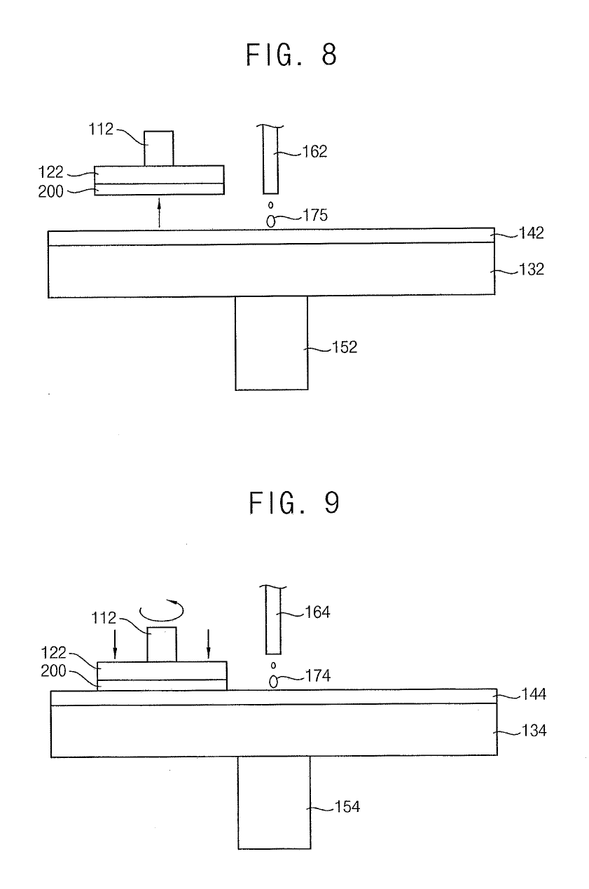

FIG. 19 illustrates a flowchart of stages of a method of forming a plug in accordance with example embodiments. This method may include processes substantially the same as or similar to those described with reference to FIGS. 3 to 11, and thus repeated detailed descriptions thereon may be omitted herein.

Referring to FIGS. 18 and 19, in step S310, an insulating interlayer on a substrate may be partially removed to form an opening exposing a top surface of the substrate.

In step S320, a barrier layer may be formed on the exposed top surface of the substrate, a sidewall of the opening, and the insulating interlayer, and a metal layer may be formed on the barrier layer to fill a remaining portion of the opening.

In step S330, a first CMP process may be performed during a first time period while pressing the substrate (via the first polishing head 122) onto an upper or polishing surface of the first polishing pad mounted on the first platen 132, so that the metal layer and the barrier layer may be first polished.

In example embodiments, the first CMP process may be performed until about half of a portion of the metal layer on the insulating interlayer is removed.

In step S340, the first polishing pad may be cleaned during a fourth time period (that is much shorter than the first time period) while keeping the substrate spaced apart from the first polishing pad on the first platen 132 via the first polishing head 122.

In example embodiments, the cleaning process may be performed on the first polishing pad by providing a cleaning solution, e.g., DIW, onto the polishing surface of the first polishing pad via the first slurry supply arm 162. The substrate having the metal layer and the barrier layer thereon may be spaced apart from the polishing surface of the first polishing pad, the metal layer and the barrier layer may not contact the DIW.

In step S350, the first rotating arm 102 may be rotated to dispose the first polishing head 122 above or facing the second platen 134, and a second CMP process may be performed during a second time period while pressing the substrate via the first polishing head 122 onto an upper or polishing surface of the second polishing pad mounted on the second platen 134 so that the metal layer and the barrier layer may be second polished. In example embodiments, the second time period may be substantially equal in duration to the first time period.

In example embodiments, the second CMP process may be performed on the metal layer and the barrier layer until a top or outer surface of the insulating interlayer is exposed, and thus a preliminary metal pattern and a preliminary barrier pattern may be formed in the insulating interlayer.

In step S360, the second polishing pad may be cleaned during the fourth time period (that is much shorter than the second time period) while keeping the substrate spaced apart from the second polishing pad on the second platen 134 via the first polishing head 122.

The cleaning process may be performed on the second polishing pad by providing a cleaning solution, e.g., DIW, onto the polishing surface of the second polishing pad via the second slurry supply arm 164. The substrate having the preliminary metal pattern and the preliminary barrier pattern thereon may be spaced apart from the polishing surface of the second polishing pad, and the preliminary metal pattern and the preliminary barrier pattern may not contact the DIW.

In step S370, the first rotating arm 102 may be rotated to dispose the first polishing head 122 above or facing the third platen 136, and a third CMP process may be performed (during a third time period) while pressing the substrate via the first polishing head 122 onto an upper or polishing surface of the third polishing pad mounted on the third platen 136 so that the preliminary metal pattern and the preliminary barrier pattern may be polished. In example embodiments, the third time period may be substantially equal in duration to the first time period.

In example embodiments, the third CMP process may be performed on the preliminary metal pattern and the preliminary barrier pattern, so that a plug including a metal pattern and a barrier pattern may be formed to a desired height in the insulating interlayer.

In step S380, the third polishing pad may be cleaned during the fourth time period (that is much shorter than the third time period) while keeping the substrate spaced apart from the third polishing pad on the third platen 136 via the first polishing head 122.

The cleaning process may be performed on the third polishing pad by providing a cleaning solution, e.g., DIW, onto the polishing surface of the third polishing pad via the third slurry supply arm 166. The substrate (having the metal pattern and the barrier pattern thereon) may be spaced apart from the polishing surface of the third polishing pad, and the metal pattern and the barrier pattern may not contact the DIW.

Before the step S310, processes substantially the same as or similar to those illustrated with reference to FIGS. 12 to 17 may be further performed on the fourth platen 139, so that an insulating interlayer pattern having a flat top surface may be formed.

As described above, performance of the CMP process on the portion of the metal layer on the insulating interlayer may be divided into two parts, and may be performed on the first and second platens 132 and 134, respectively. Thus, performing the CMP process on the portion of the metal layer (which consumes or requires a relatively large amount of time) may be divided into two parts, each of which may be performed during a time period that is substantially equal to or similar to a time for the CMP process on a portion of the metal layer in the opening and a portion of the insulating interlayer adjacent thereto (which consume or require a relatively small amount of time).

Accordingly, the CMP processes for forming plugs on the substrates, respectively, in the polishing chamber may be performed during substantially the same or similar time period on each of the platens. For example, when the first CMP process is performed on the first platen 132, the substrate may not wait on the second platen 134 until the first CMP process is finished, or the cleaning process may not be performed. For example, the design of the apparatus facilitates simultaneous performance of different CMP processes.

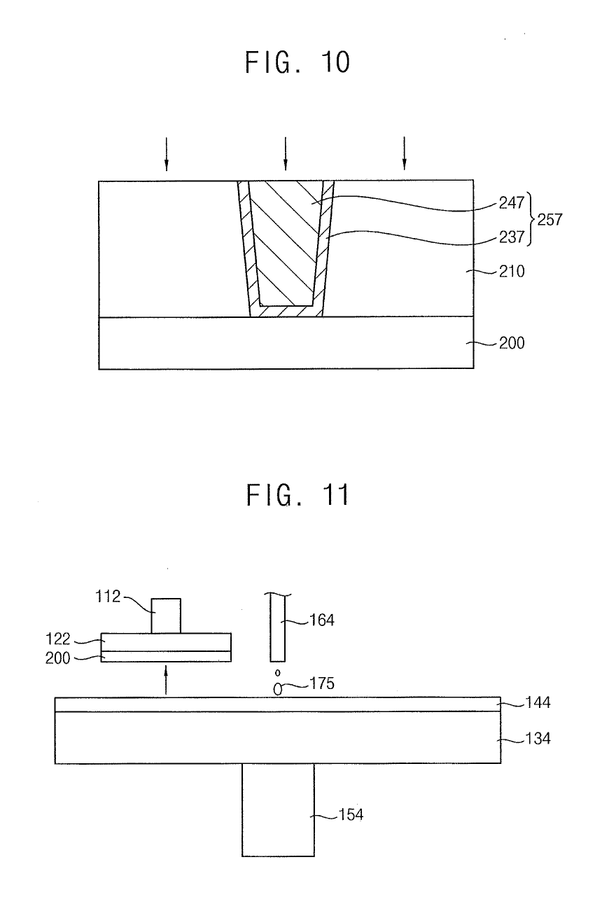

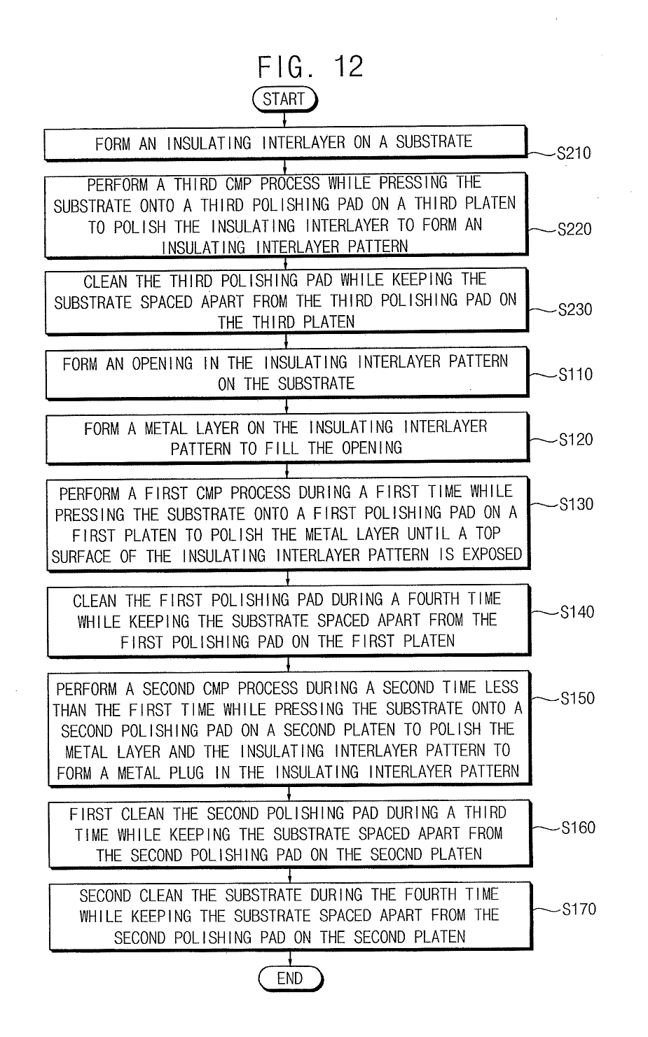

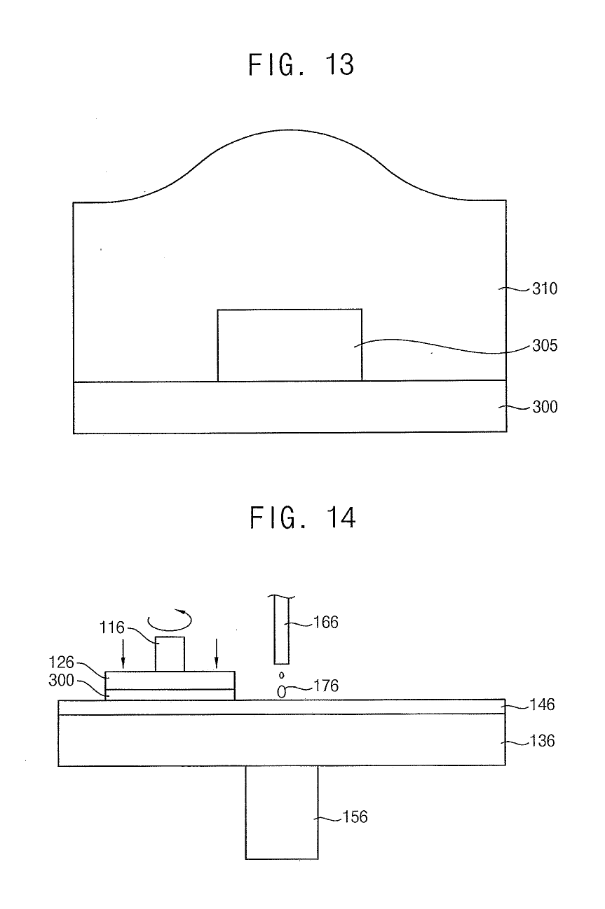

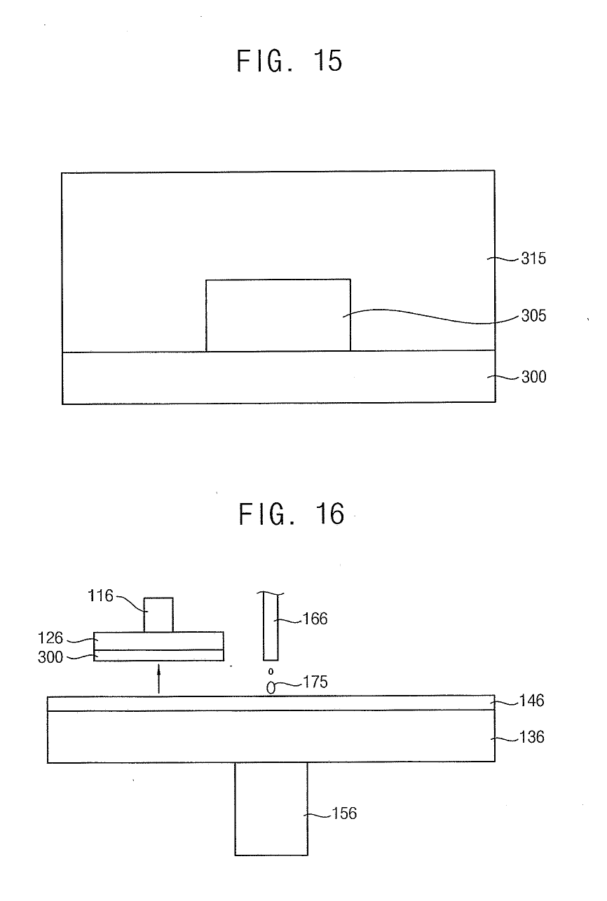

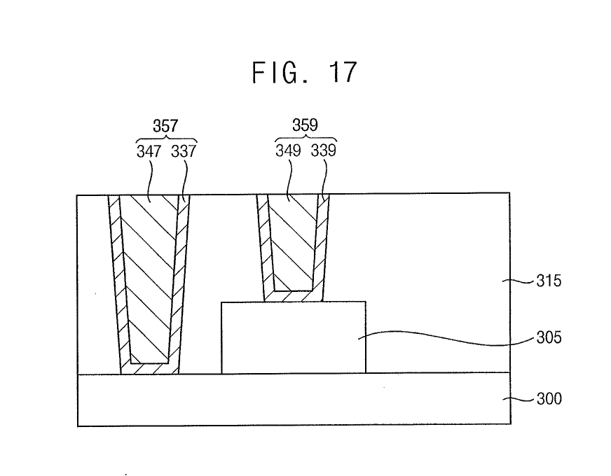

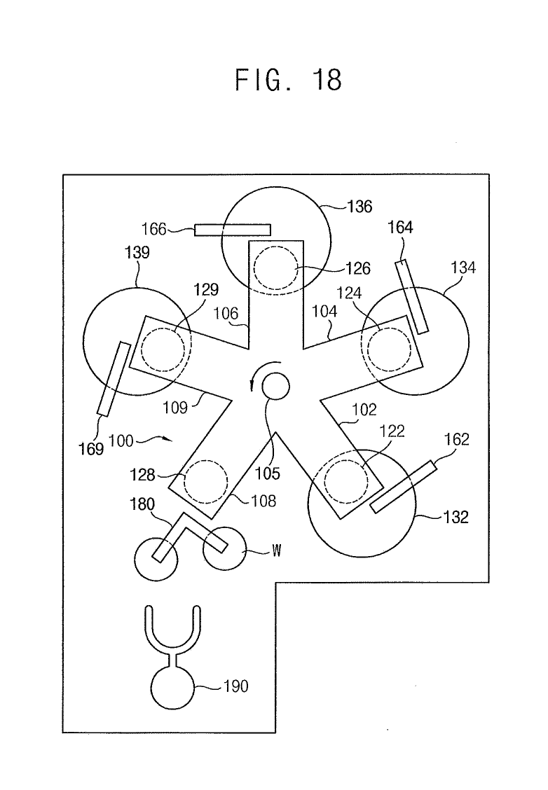

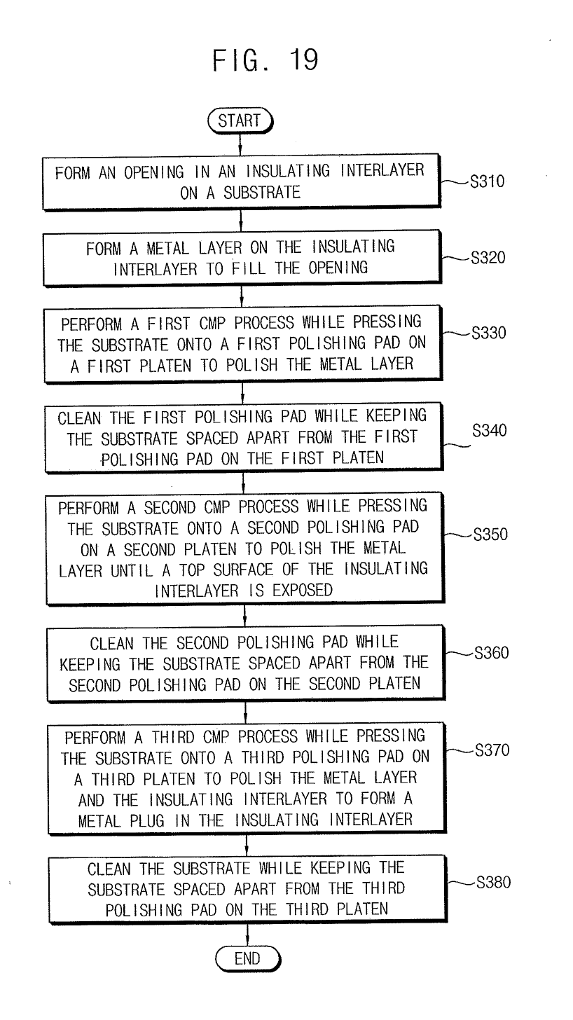

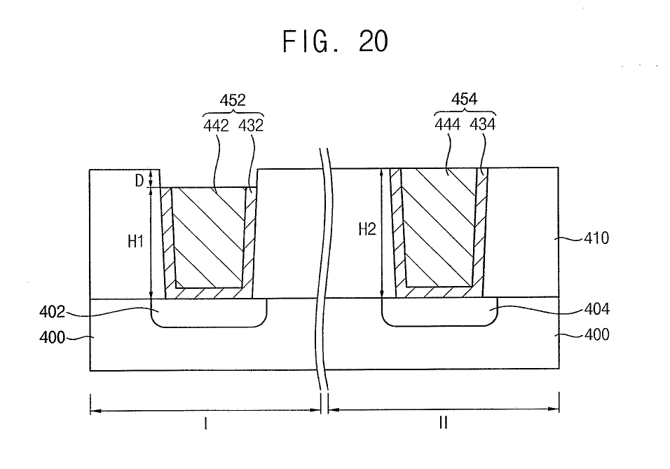

FIG. 20 illustrates a cross-sectional view of plugs formed by the method of forming the plugs in accordance with example embodiments.

Referring to FIG. 20, first and second plugs 452 and 454 may be formed on a substrate 400 including first and second regions I and II.

In example embodiments, the first and second regions I and II may be a positive-channel metal oxide semiconductor (PMOS) region and a negative-channel metal oxide semiconductor (NMOS) region, respectively.

A first impurity region 402 may be formed at an upper portion of the first region I of the substrate 400, and a second impurity region 404 may be formed at an upper portion of the second region II of the substrate 400. The first and second impurity regions 402 and 404 may be doped with p-type and n-type impurities, respectively.

An insulating interlayer 410 may be formed on the substrate 400. The first and second plugs 452 and 454 may penetrate through the insulating interlayer 410, and may contact top surfaces of the first and second impurity regions 402 and 404, respectively.

In example embodiments, the first plug 452 may include a first metal pattern 442 and a first barrier pattern 432 covering a bottom and a sidewall of the first metal pattern 442, and the second plug 454 may include a second metal pattern 444 and a second barrier pattern 434 covering a bottom and a sidewall of the second metal pattern 444. Each of the first and second metal patterns 442 and 444 may include a metal, e.g., tungsten, copper, aluminum, etc., and each of the first and second barrier patterns 432 and 434 may include a metal nitride, e.g., titanium nitride, tantalum nitride, etc., or a metal, e.g., titanium, tantalum, etc.

In example embodiments, a top surface of the second plug 454 may have a second height H2 from a top surface of the substrate 400, and a top surface of the first plug 452 may have a first height H1 from the top surface of the substrate 400, which may be less than the second height H2 by a difference D.

The first and second plugs 452 and 454 may be formed by the method of forming the plug described with reference to FIGS. 3 to 11. As illustrated above, no recess may be formed in the plug formed by the above method, and thus when a plurality of plugs is formed, the plugs may have a constant or uniform height regardless of a region of the substrate 400.

In some embodiments, the plugs may be formed to have different heights from each other according to the regions, which is shown in FIG. 20.

For example, when a CMP process is performed on a metal layer including tungsten to form a plug, a tungsten oxide layer on the metal layer may contact DIW so that the acidity of the tungsten layer may change or increase. Thus, the tungsten oxide layer may be transformed into an electrolyte of oxidized tungsten, e.g., WO₄²⁻, WO₅²⁻, etc., and particularly, when a positive potential is formed in the metal layer, this transformation may easily occur.

As shown in FIG. 20, the first impurity region 402 doped with p-type impurities may be formed under the first plug 452, and a positive potential may be formed in the first plug 452 when compared to the second plug 454 (under which the second impurity region 404 doped with n-type impurities is formed). Thus, when a CMP process and a cleaning process for forming the first plug 452 are performed, the tungsten oxide layer may be easily transformed into the electrolyte of oxidized tungsten.

Accordingly, a recess may be formed at an upper portion of the first plug 452, and the first height H1 of the top surface of the first plug 452 may be lower or shorter than the second height H2 of the top surface of the second plug 454. However, in accordance with example embodiments, the cleaning process may be performed while the substrate 400 is spaced apart from the polishing pad, and the formation of the recess at the upper portion of the first plug 452 may be reduced.

In example embodiments, the second height H2 of the top surface of the second plug 454 from the top surface of the substrate 400 may be about 50 nm, and the first height H1 of the top surface of the first plug 452 from the top surface of the substrate 400 may be equal to or more than about 40 nm. Thus, the difference D between the first and second heights H1 and H2 may be equal to or less than about 20% of the second height H2. For example, the first height H1 may be equal to or more than about 80% of the second height H2.

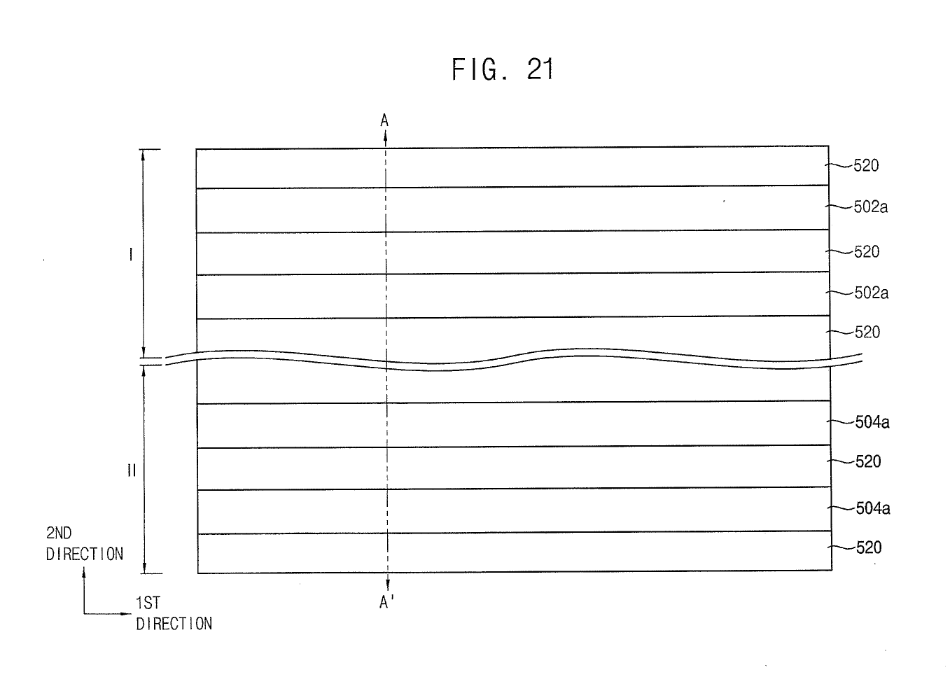

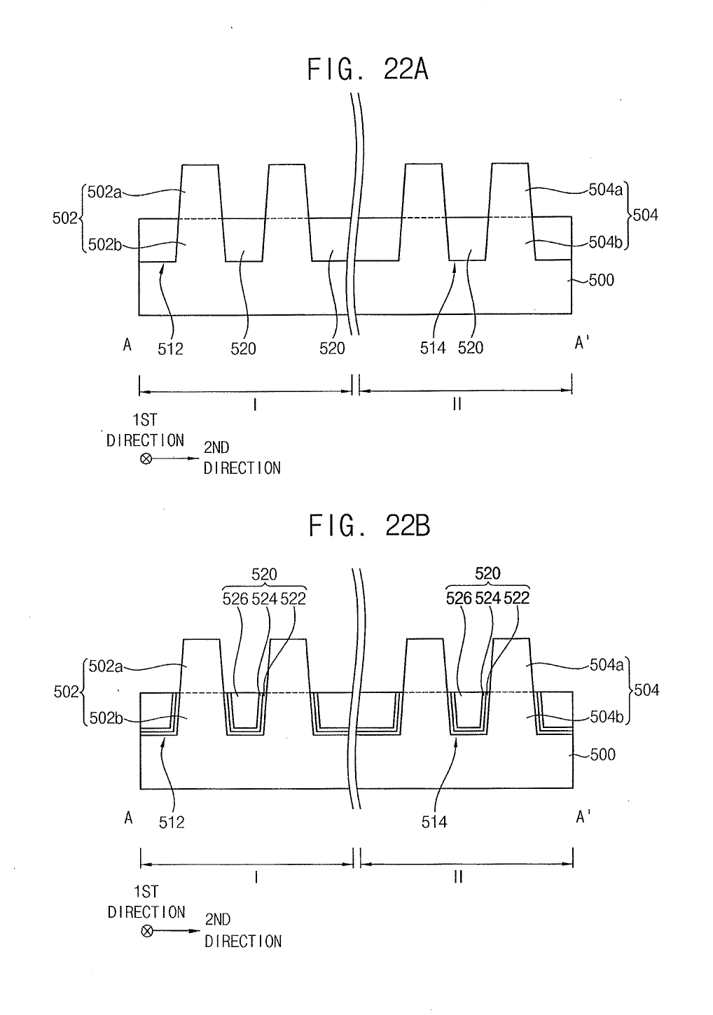

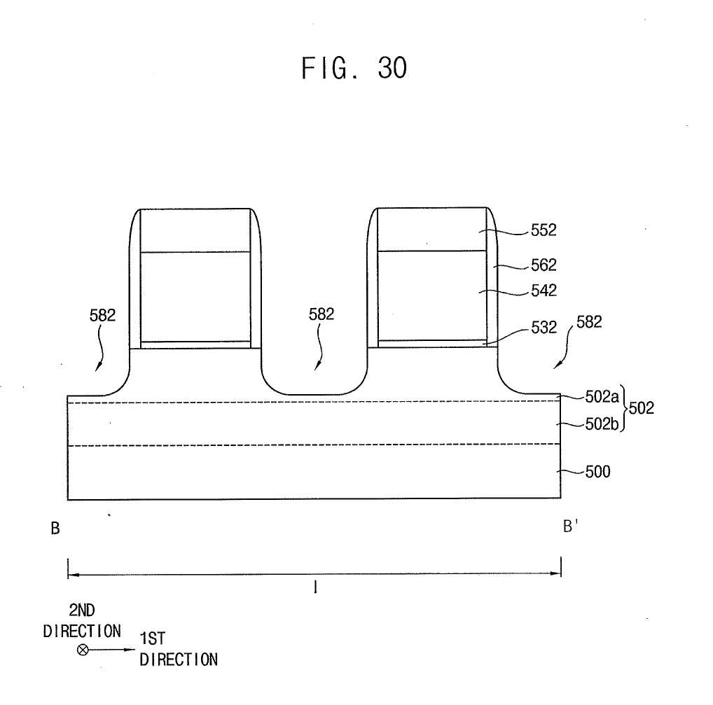

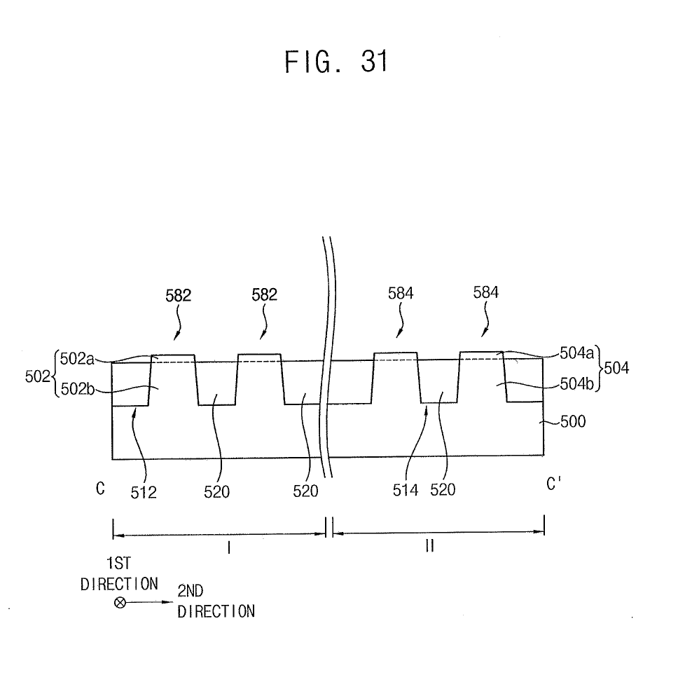

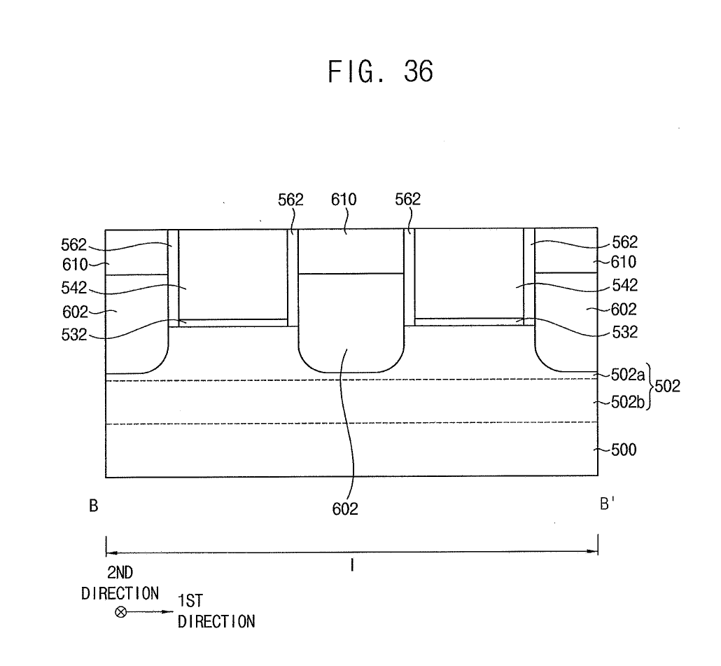

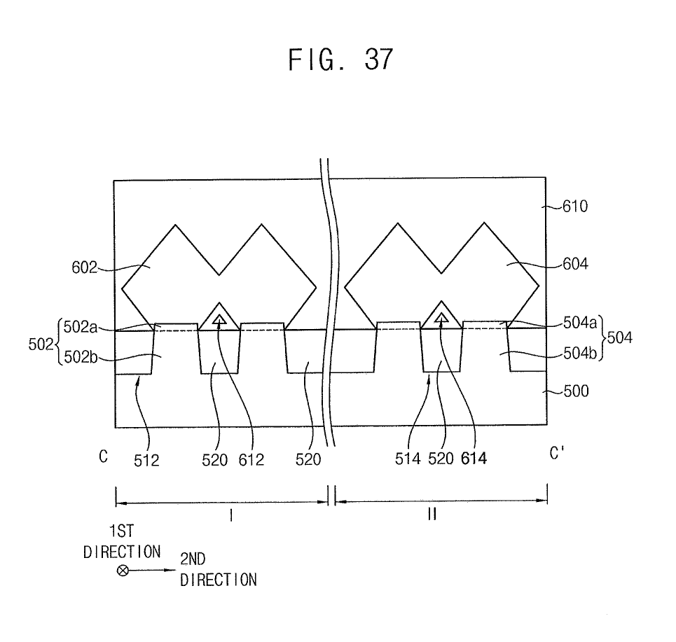

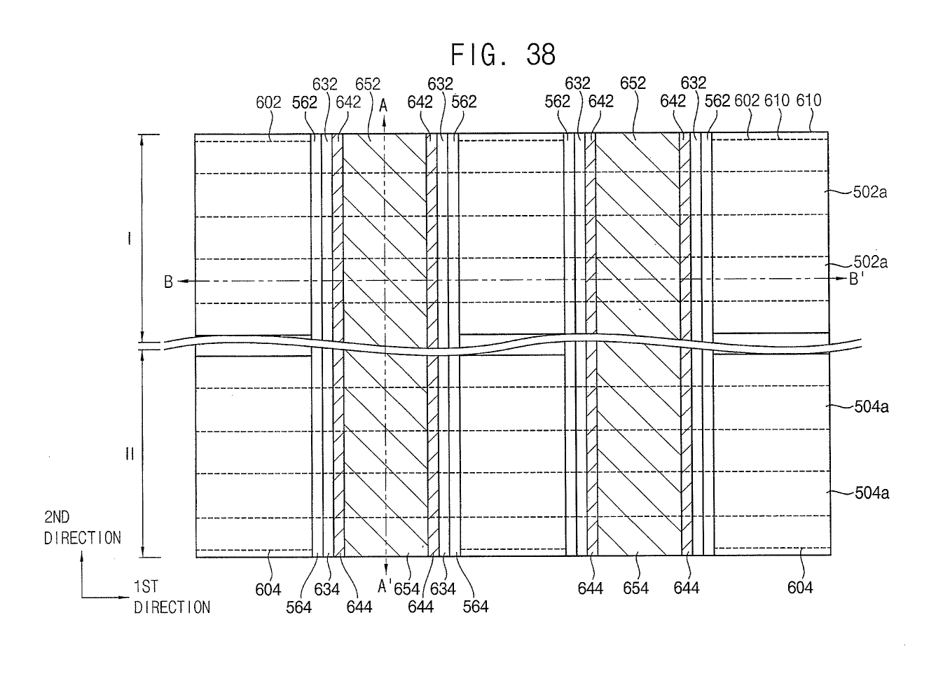

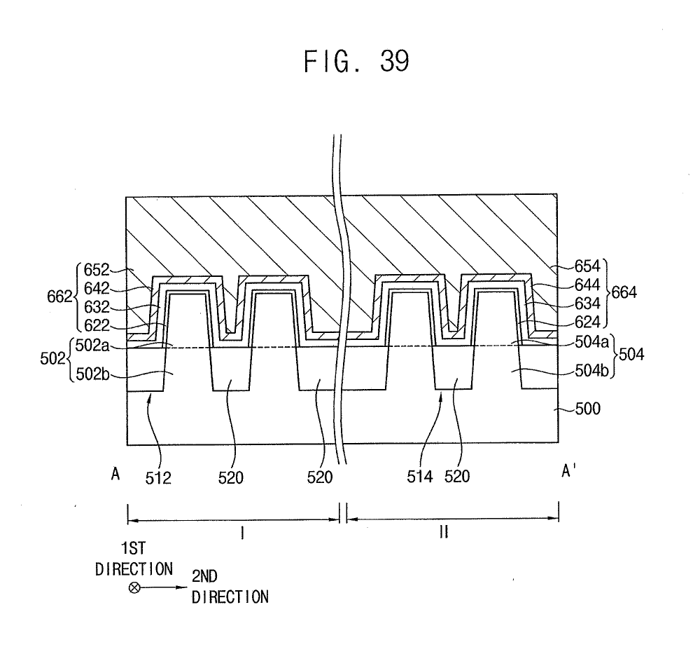

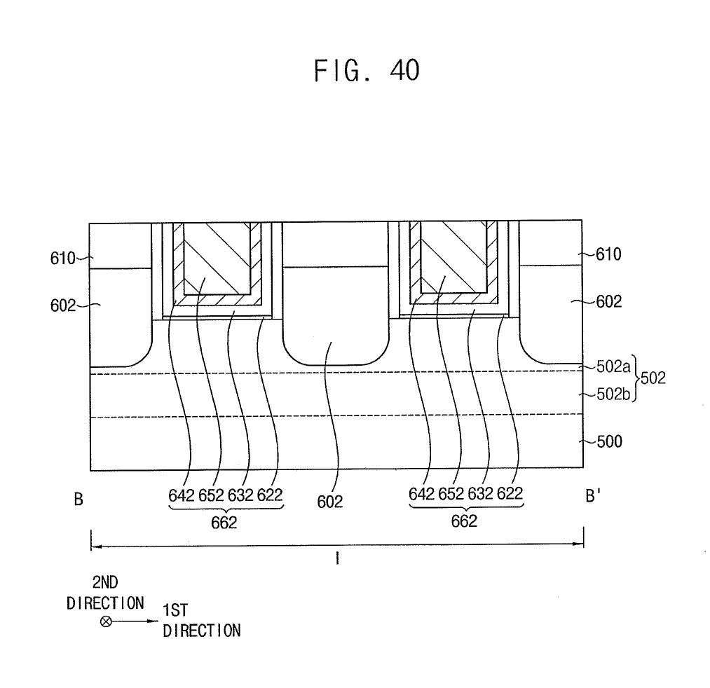

FIGS. 21 to 53 illustrate plan views and cross-sectional views of stages of a method of manufacturing a semiconductor device in accordance with example embodiments. Particularly, FIGS. 21, 23, 26, 29, 32, 35, 38, and 41 illustrate plan views, and FIGS. 22, 24-25, 27-28, 30-31, 33-34, 36-37, 39-40 and 42-53 illustrate cross-sectional views.

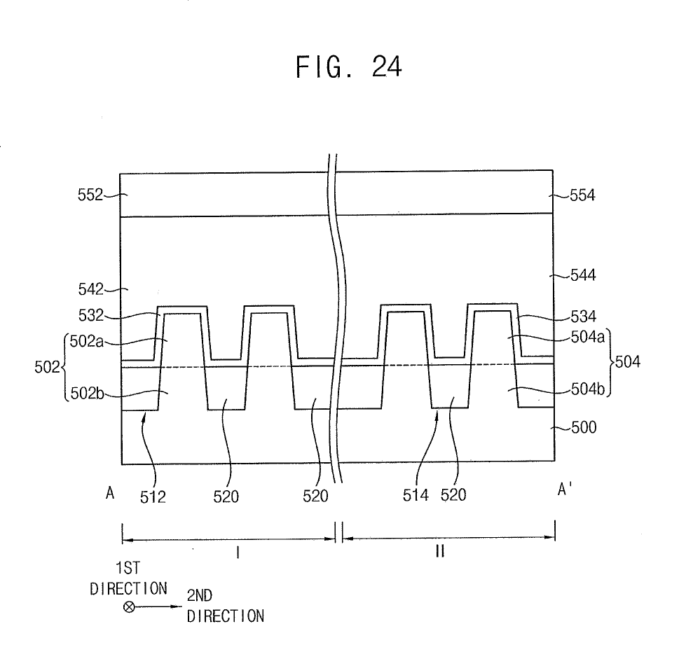

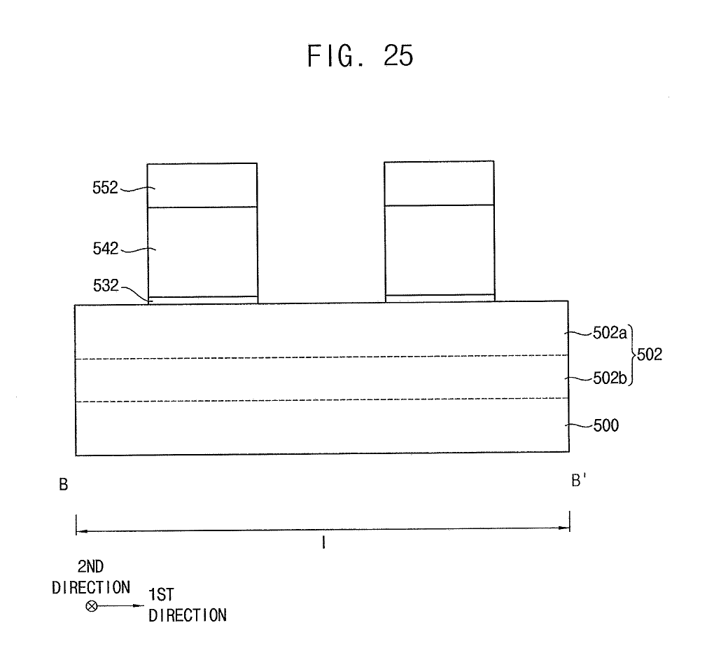

FIGS. 22 and 24 illustrate cross-sectional views taken along lines A-A′ of corresponding plan views, FIGS. 25, 27, 30, 33, 36, 39, 40, 42, 44, 46-51 and 53 illustrate cross-sectional views taken along lines B-B′ of corresponding plan views, and FIGS. 28, 31, 34, 37, 43, 45 and 52 illustrate cross-sectional views taken along lines C-C′ of corresponding plan views.

This method of manufacturing the semiconductor device may include processes substantially the same as or similar to those described with reference to FIGS. 1 to 11, FIGS. 12 to 17, FIGS. 18 to 19, or FIG. 20, and thus repeated detailed descriptions thereon may be omitted herein.

Referring to FIGS. 21 and 22A, an upper portion of a substrate 500 may be partially removed to form first and second recesses 512 and 514, and an isolation pattern 520 may be formed to fill a lower portion of each of the first and second recesses 512 and 514.

The substrate 500 may include first and second regions I and II. In example embodiments, the first and second regions I and II may be PMOS and NMOS regions, respectively. The first and second recesses 512 and 514 may be formed at upper portions of the first and second regions I and II, respectively, of the substrate 500.

In example embodiments, the isolation pattern 520 may be formed by forming an isolation layer on the substrate 500 to sufficiently fill the first and second recesses 512 and 514, planarizing the isolation layer until a top surface of the substrate 500 may be exposed, and removing an upper portion of the isolation layer to expose upper portions of the first and second recesses 512 and 514. The isolation layer may be formed of an oxide, e.g., silicon oxide.

As the isolation pattern 520 may be formed on the substrate 500, a field region having a top surface covered by the isolation pattern 520 and first and second active regions 502 and 504 having top surfaces not covered by the isolation pattern 520 may be defined in the first and second regions I and II, respectively, of the substrate 500. Each of the first and second active regions 502 and 504 may have a fin-like shape protruding from the substrate 500, and thus may be referred to as first and second active fins, respectively.

In example embodiments, each of the first and second active fins 502 and 504 may be formed to extend in a first direction substantially parallel to a top surface of the substrate 500, and a plurality of first active fins 502 and a plurality of second active fins 504 may be formed in a second direction substantially parallel to the top surface of the substrate 500 and substantially perpendicular to the first direction.

In example embodiments, the first active fin 502 may include a first lower active pattern 502b of which a sidewall may be covered by the isolation pattern 520, and a first upper active pattern 502a protruding from a top surface of the isolation pattern 520. Additionally, the second active fin 504 may include a second lower active pattern 502b of which a sidewall may be covered by the isolation pattern 520, and a second upper active pattern 504a protruding from the top surface of the isolation pattern 520. In example embodiments, each of the first and second upper active patterns 502a and 504a may have a width in the second direction slightly smaller than a width of each of the first and second lower active patterns 502b and 504b in the second direction.

Referring to FIG. 22B, the isolation pattern 520 may have a multiple layer structure.

Particularly, the isolation pattern 520 may include first and second liners 522 and 524 sequentially stacked on an inner wall of each of the first and second recesses 512 and 514, and a filling insulation layer 526 filling a remaining portion of each of the first and second recesses 512 and 514 on the second liner 524.

The first liner 522 may be formed of an oxide, e.g., silicon oxide, and the second liner 524 may be formed of polysilicon or a nitride, e.g., silicon nitride.

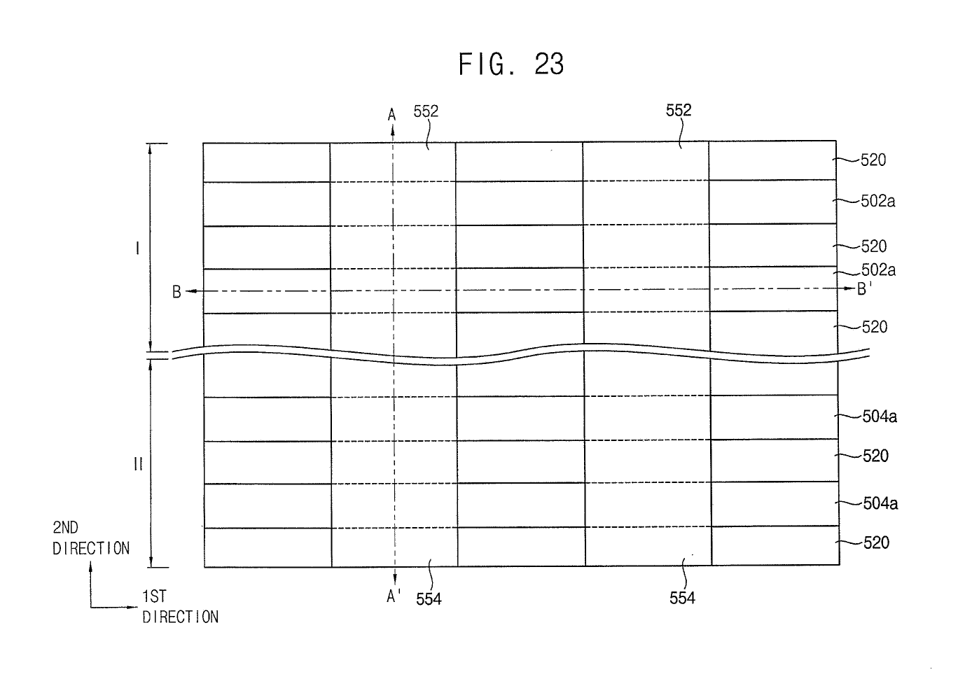

Referring to FIGS. 23 to 25, first and second dummy gate structures may be formed on the first and second regions I and II, respectively, of the substrate 500.

The first and second dummy gate structures may be formed by sequentially forming a dummy gate insulation layer, a dummy gate electrode layer, and a dummy gate mask layer on the first and second active fins 502 and 504 of the substrate 500 and the isolation pattern 520, patterning the dummy gate mask layer by a photolithography process using a photoresist pattern to form first and second dummy gate masks 552 and 554, and sequentially etching the dummy gate electrode layer and the dummy gate insulation layer using the first and second dummy gate masks 552 and 554 as an etching mask. Thus, the first dummy gate structure may be formed to include a first dummy gate insulation pattern 532, a first dummy gate electrode 542 and the first dummy gate mask 552 sequentially stacked on the first active fin 502 of the substrate 500 and a portion of the isolation pattern 520 adjacent to the first active fin 502 in the second direction. The second dummy gate structure may be formed to include a second dummy gate insulation pattern 534, a second dummy gate electrode 544 and the second dummy gate mask 554 sequentially stacked on the second active fin 504 of the substrate 500 and a portion of the isolation pattern 520 adjacent to the second active fin 504 in the second direction.

The dummy gate insulation layer may be formed of an oxide, e.g., silicon oxide, the dummy gate electrode layer may be formed of, e.g., polysilicon, and the dummy gate mask layer may be formed of a nitride, e.g., silicon nitride. The dummy gate insulation layer may be formed by a CVD process, an ALD process, or the like. Alternatively, the dummy gate insulation layer may be formed by a thermal oxidation process on an upper portion of the substrate 500, and in this case, the dummy gate insulation layer may not be formed on the isolation pattern 520 but may be formed only on the first and second active fins 502 and 504. The dummy gate electrode layer and the dummy gate mask layer may be also formed by a CVD process, an ALD process, etc.

In example embodiments, each of the first and second dummy gate structures may be formed to extend in the second direction on each of the first and second active fins 502 and 504, respectively, of the substrate 500 and the isolation pattern 520, and a plurality of first dummy gate structures and a plurality of second dummy gate structures may be formed in the first direction.

An ion implantation process may be further performed to form an impurity region at an upper portion of each of the first and second active fins 502 and 504 adjacent the first and second dummy gate structures, respectively.

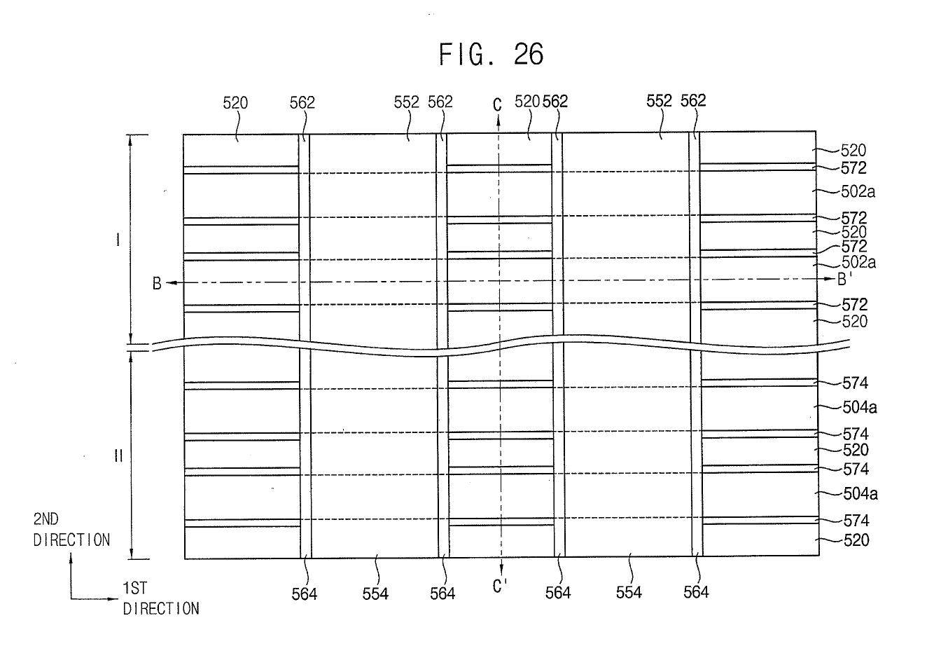

Referring to FIGS. 26 to 28, first and second gate spacers 562 and 564 may be formed on sidewalls of the first and second dummy gate structures, respectively. Additionally, first and second fin spacers 572 and 574 may be formed on sidewalls of the first and second active fins 502 and 504, respectively.

In example embodiments, the first and second gate spacers 562 and 564 and the first and second fin spacers 572 and 574 may be formed by forming a spacer layer on the first and second dummy gate structures, the first and second active fins 502 and 504 and the isolation pattern 520, and anisotropically etching the spacer layer. The spacer layer may be formed of a nitride, e.g., silicon nitride, silicon carbonitride, etc.

Each of the first and second gate spacers 562 and 564 may be formed on the sidewalls of each of the first and second dummy gate structures opposite to each other in the first direction, and each of the first and second fin spacers 572 and 574 may be formed on the sidewalls of each of the first and second active fins 502 and 504 opposite to each other in the second direction.

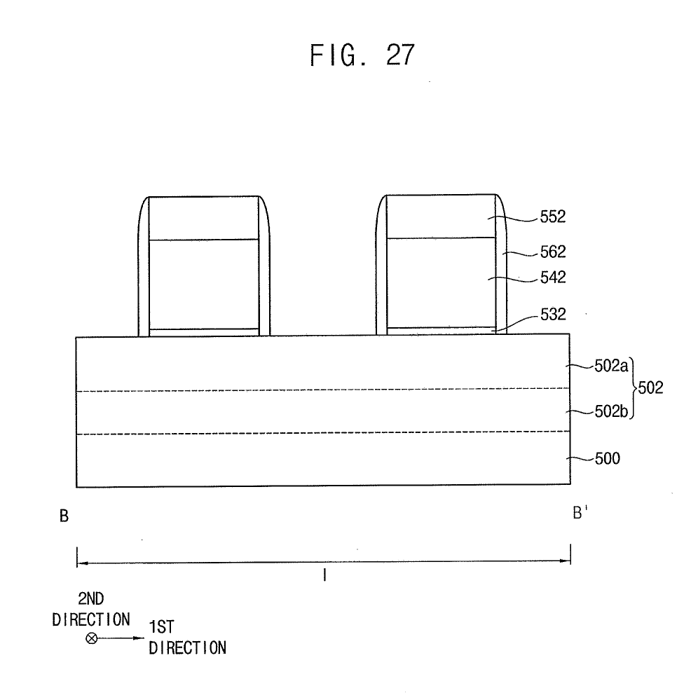

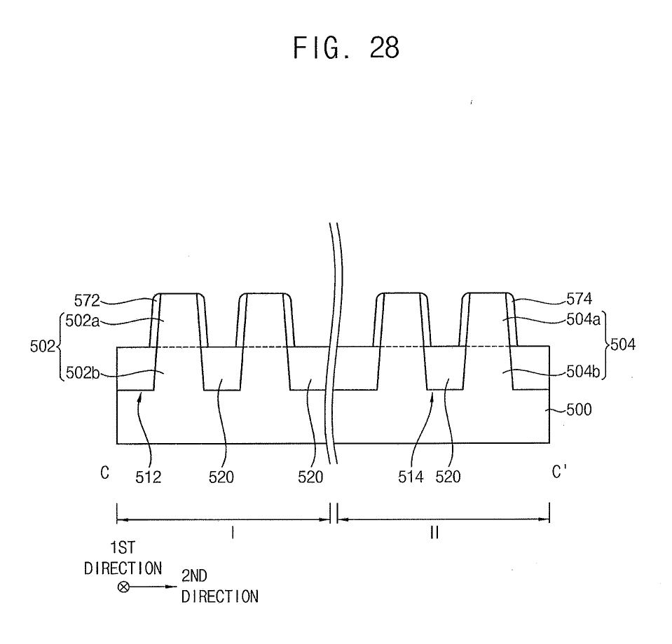

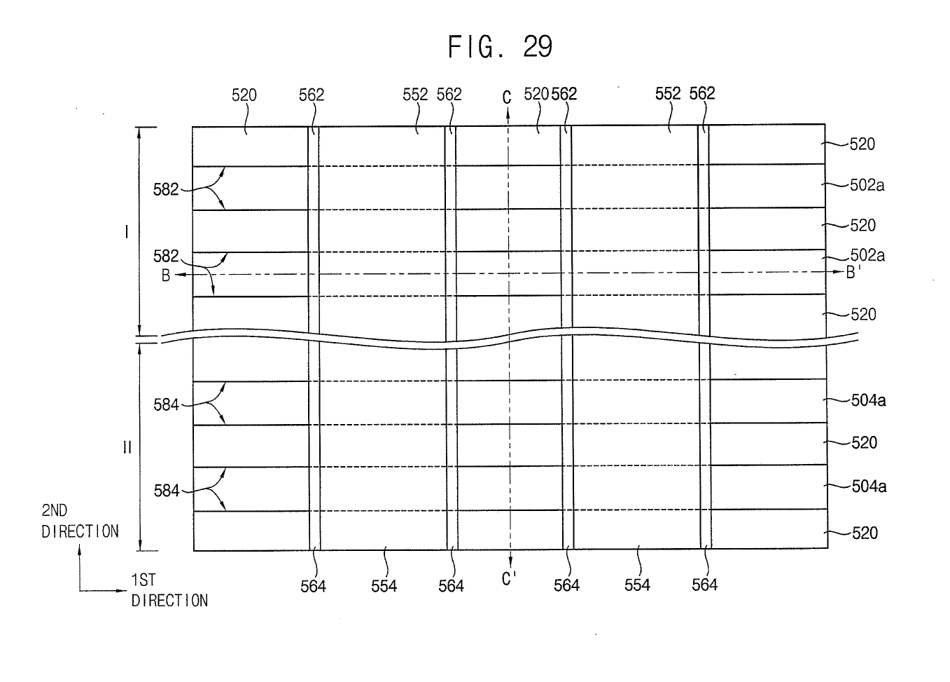

Referring to FIGS. 29 to 31, upper portions of the first and second active fins 502 and 504 adjacent the first and second dummy gate structures, respectively, may be etched to form third and fourth recesses 582 and 584, respectively.

Particularly, the upper portions of the first and second active fins 502 and 504 may be etched using the first and second dummy gate structures and the first and second gate spacers 562 and 564 as an etching mask to form the third and fourth recesses 582 and 584. In the etching process, the first and second fin spacers 572 and 574 may be also removed. FIGS. 29 to 31 show that the first and second upper active patterns 502a and 504a in the first and second active fins 502 and 504, respectively, is partially etched to form the third and fourth recesses 582 and 584, respectively. For example, each of the third and fourth recesses 582 and 584 may be formed by partially removing each of the first and second upper active patterns 502a and 504a to expose each of the first and second lower active patterns 502b and 504b, and further, a portion of each of the first and second lower active patterns 502b and 504b may be removed when each of the third and fourth recesses 582 and 584 is formed.

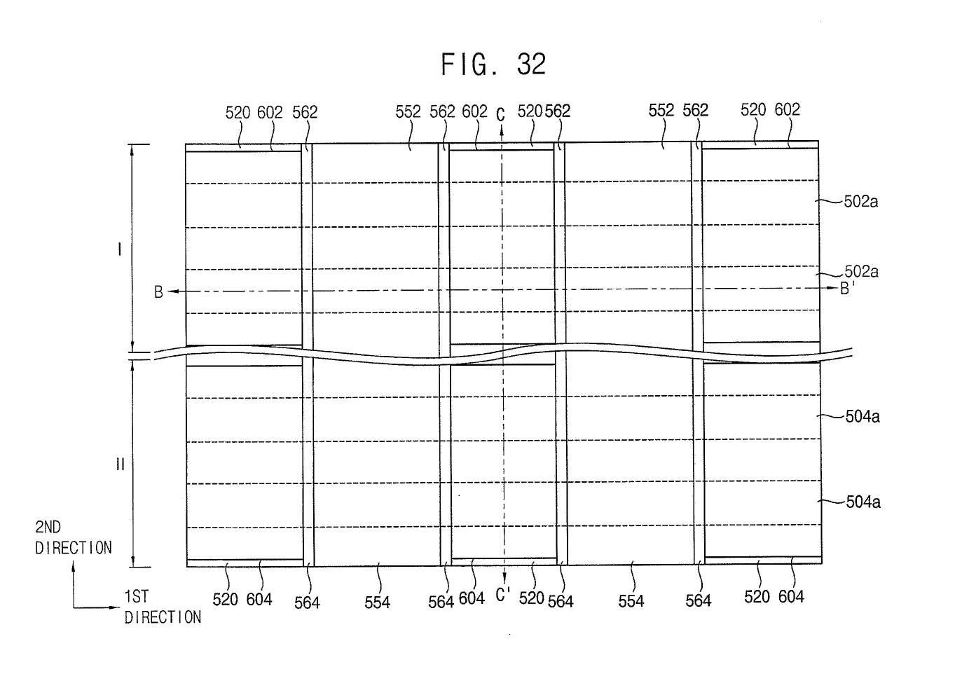

Referring to FIGS. 32, 33A and 34A, first and second source/drain layers 602 and 604 may be formed on the first and second active fins 502 and 504, respectively, to fill the third and fourth recesses 582 and 584, respectively.

In example embodiments, the first and second source/drain layers 602 and 604 may be formed by a selective epitaxial growth (SEG) process using top surfaces of the first and second active fins 502 and 504 exposed by the third and fourth recesses 582 and 584, respectively, as a seed.

In example embodiments, the first source/drain layer 602 may be formed by a SEG process using a silicon source gas, e.g., dichlorosilane (SiH₂Cl₂) gas, and a germanium source gas, e.g., germane (GeH₄) gas to form a single crystalline silicon-germanium layer. A p-type impurity source gas, e.g., diborane (B₂H₆) gas may be also used to form a single crystalline silicon-germanium layer doped with p-type impurities. Accordingly, the first source/drain layer 602 may serve as a source/drain region of a PMOS transistor.

In example embodiments, the second source/drain layer 604 may be formed by a SEG process using a silicon source gas, e.g., disilane (Si₂H₆) gas and a carbon source gas, e.g., monomethylsilane (SiH₃CH₃) gas to form a single crystalline silicon carbide layer. Alternatively, the second source/drain layer 604 may be formed by a SEG process using only a silicon source gas, e.g., disilane (Si₂H₆) gas to form a single crystalline silicon layer. An n-type impurity source gas, e.g., phosphine (PH₃) gas may be also used to form a single crystalline silicon carbide layer doped with n-type impurities or a single crystalline silicon layer doped with n-type impurities. Accordingly, the second source/drain layer 604 may serve as a source/drain region of an NMOS transistor.

Each of the first and second source/drain layers 602 and 604 may grow both in vertical and horizontal directions, and thus may not only fill each of the third and fourth recesses 582 and 584 but also contact a portion of each of the first and second gate spacers 562 and 564. An upper portion of each of the first and second source/drain layers 602 and 604 may have a cross-section taken along the second direction of which a shape may be pentagon or hexagon. When the first active fins 502 or the second active fins 504 are spaced apart from each other in the second direction by a short distance, neighboring ones of the first source/drain layers 602 in the second direction or neighboring ones of the second source/drain layers 604 in the second direction may be merged with each other to form a single layer. FIGS. 32, 33A and 34A show that one first source/drain layer 602 merged from a plurality of first source/drain layers 602 that have grown on neighboring ones of the first active fins 502, and one second source/drain layer 604 merged from a plurality of second source/drain layers 604 that have grown on neighboring ones of the second active fins 504 are shown.

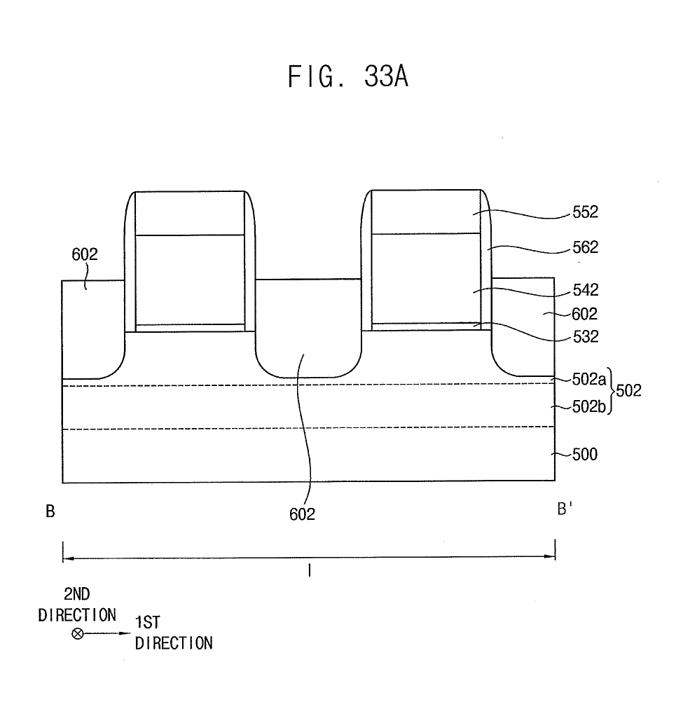

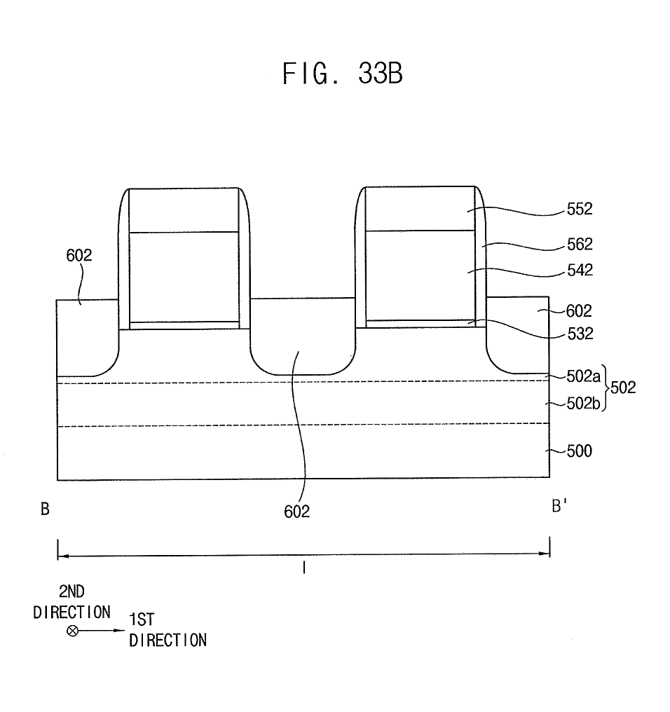

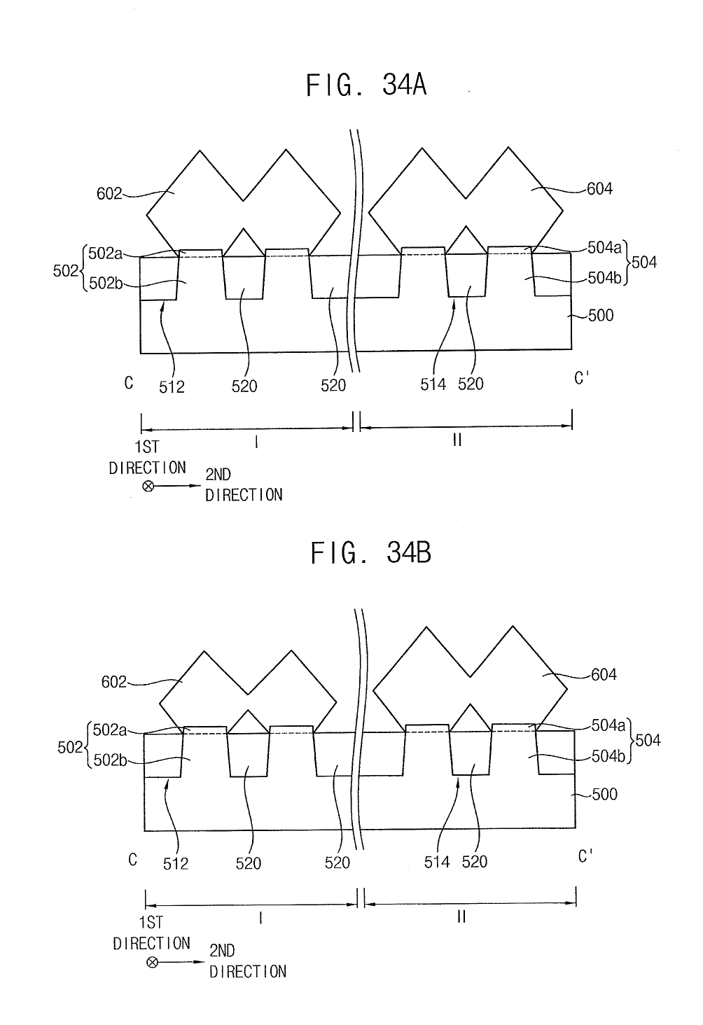

Referring to FIGS. 33B and 34B, top surfaces of the first and second source/drain layers 602 and 604 may have heights different from each other.

In example embodiments, the first source/drain layer 602 in the first region I may have a top surface lower than that of a top surface of the second source/drain layer 604 in the second region II.

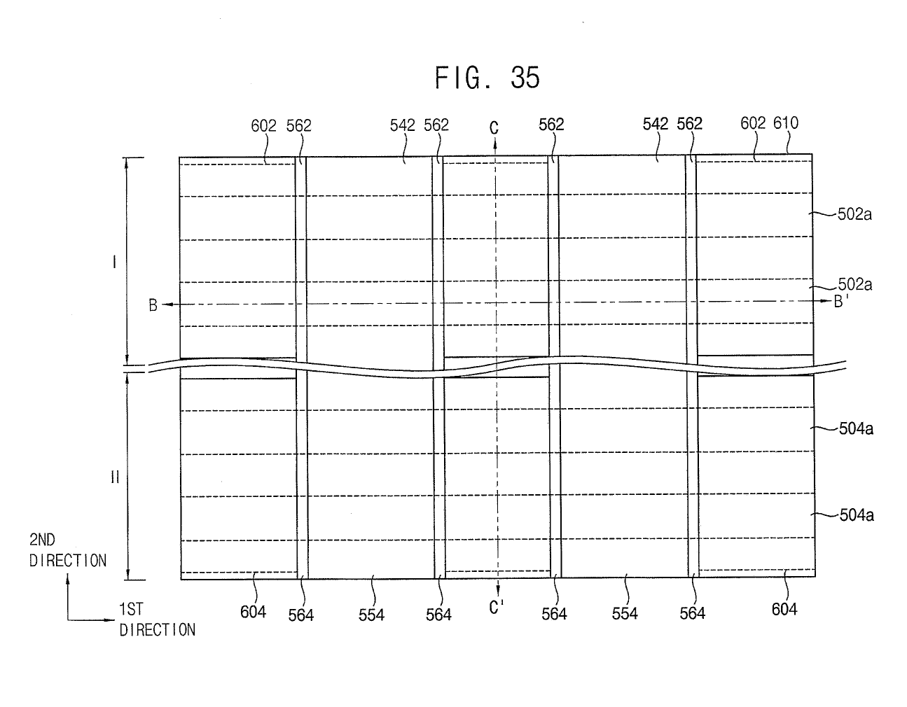

Referring to FIGS. 35 to 37, an insulation layer 610 may be formed on the first and second active fins 502 and 504 and the isolation pattern 520 to cover the first and second dummy gate structures, the first and second gate spacers 562 and 564 and the first and second source/drain layers 602 and 604, and the insulation layer 610 may be planarized until a top surface of the first and second dummy gate electrodes 542 and 544 of the first and second dummy gate structures, respectively, may be exposed. The first and second dummy gate masks 552 and 554 may be also removed, and upper portions of the first and second gate spacers 562 and 564 may be also removed. The insulation layer 610 may not completely fill a first space between the merged first source/drain layer 602 and the isolation pattern 520 or a second space between the merged second source/drain layer 604 and the isolation pattern 520, and thus first and second air gaps 612 and 614 may be formed in the first and second spaces, respectively.

The insulation layer 610 may be formed of silicon oxide, e.g., Tonen SilaZene (TOSZ). The planarization process may be performed by a CMP process and/or an etch back process.

Referring to FIGS. 38 to 40, the exposed first and second dummy gate electrodes 542 and 544, and the first and second dummy gate insulation patterns 532 and 534 thereunder may be removed to form first and second openings exposing top surfaces of the first and second active fins 502 and 504, respectively, and inner sidewalls of the first and second gate spacers 562 and 564, respectively. First and second gate structures 662 and 664 may be formed to fill the first and second openings, respectively.

Particularly, after a thermal oxidation process may be performed on the exposed top surfaces of the first and second active fins 502 and 504, respectively, to form first and second interface patterns 622 and 624, respectively, a gate insulation layer and a work function control layer may be sequentially formed on the first and second interface patterns 622 and 624, the isolation pattern 520, the first and second gate spacers 562 and 564 and the insulation layer 610, and a gate electrode layer may be formed on the work function control layer to fill remaining portions of the first and second openings, respectively.

The gate insulation layer may be formed of a metal oxide having a high dielectric constant, e.g., hafnium oxide, tantalum oxide, zirconium oxide, or the like, by a CVD process, a PVD process, an ALD process, or the like. The work function control layer may be formed of a metal nitride or a metal alloy, e.g., titanium nitride, titanium aluminum, titanium aluminum nitride, tantalum nitride, tantalum aluminum nitride, etc., and the gate electrode layer may be formed of a material having a low resistance, e.g., a metal such as aluminum, copper, tantalum, etc., or a metal nitride thereof. The work function control layer and the gate electrode layer may be formed by a CVD process, a PVD process, an ALD process, or the like. In an example embodiment, a heat treatment process, e.g., a rapid thermal annealing (RTA) process, a spike rapid thermal annealing (spike RTA) process, a flash rapid thermal annealing (flash RTA) process or a laser annealing process may be further performed on the gate electrode layer.

The first and second interface patterns 622 and 624 may be formed by a CVD process, a PVD process, an ALD process instead of the thermal oxidation process, and in this case, the first and second interface patterns 622 and 624 may be formed not only on the top surfaces of the first and second active fins 502 and 504, respectively, but also on the top surface of the isolation layer pattern 520 and the inner sidewalls of the first and second gate spacers 562 and 564, respectively.

The gate electrode layer, the work function control layer and the gate insulation layer may be planarized until the top surface of the insulation layer 610 may be exposed to form a first gate insulation pattern 632 and a first work function control pattern 642 sequentially stacked on the top surfaces of the first interface pattern 632 and the isolation pattern 520 and the inner sidewall of the first gate spacer 562, and a first gate electrode 652 filling a remaining portion of the first opening on the first work function control pattern 642. Additionally, a second gate insulation pattern 634 and a second work function control pattern 644 sequentially stacked on the top surfaces of the second interface pattern 634 and the isolation pattern 520 and the inner sidewall of the second gate spacer 564, and a second gate electrode 654 filling a remaining portion of the second opening on the second work function control pattern 644 may be formed.

Thus, a bottom and a sidewall of each of the first and second gate electrodes 652 and 654 may be covered by each of the first and second work function control patterns 642 and 644. In example embodiments, the planarization process may be performed by a CMP process and/or an etch back process.

The first interface pattern 622, the first gate insulation pattern 632, the first work function control pattern 642 and the first gate electrode 652 sequentially stacked may form the first gate structure 662, and the first gate structure 662 and the first source/drain layer 602 may form a PMOS transistor. Additionally, the second interface pattern 624, the second gate insulation pattern 634, the second work function control pattern 644 and the second gate electrode 654 sequentially stacked may form the second gate structure 664, and the second gate structure 664 and the second source/drain layer 604 may form an NMOS transistor.

Referring to FIGS. 56 to 58, a lower capping layer 670 and a first insulating interlayer 680 may be sequentially formed on the insulation layer 610, the gate structure 660, and the gate spacer 560, and first and second contact plugs 700 and 705 may be formed through the insulation layer 610 and the first insulating interlayer 680 to contact top surfaces of the source/drain layers 600.

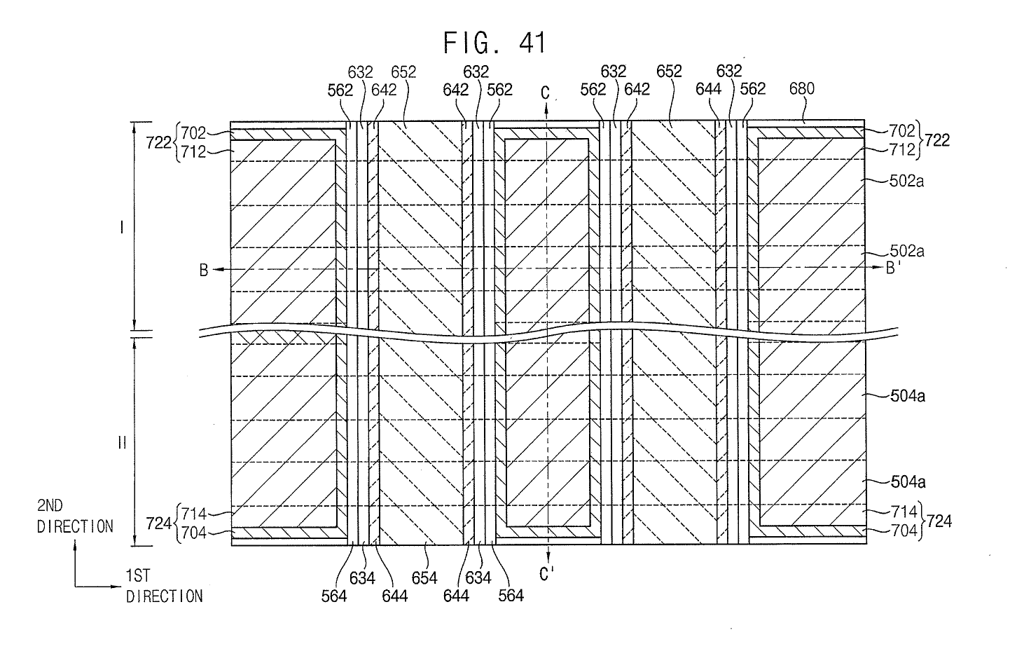

Referring to FIGS. 41, 42A and 43A, a capping layer 670 and a first insulating interlayer 680 may be sequentially formed on the insulation layer 610, the first and second gate structures 662 and 664, and the first and second gate spacers 562 and 564, and first and second contact plugs 722 and 724 may be formed through the insulation layer 610 and the first insulating interlayer 680 to contact top surfaces of the first and second source/drain layers 602 and 604, respectively.

The first insulating interlayer 680 may be formed of silicon oxide, e.g., tetra ethyl ortho silicate (TEOS).

In example embodiments, the first and second contact plugs 722 and 724 may be formed by processes substantially the same as or similar to those described with reference to FIGS. 1 to 11. Thus, the first and second contact plugs 722 and 724 may be formed to have top surfaces substantially coplanar with each other and have no recess thereon in the PMOS and NMOS regions, respectively.

The first contact plug 722 may include a first metal pattern 712 and a first barrier pattern 702 (covering a bottom and a sidewall of the first metal pattern 712). The second contact plug 724 may include a second metal pattern 714 and a second barrier pattern 704 (covering a bottom and a sidewall of the second metal pattern 714). Each of the first and second metal patterns 712 and 714 may be formed of a metal, e.g., tungsten, copper, aluminum, etc., and each of the first and second barrier patterns 702 and 704 may be formed of a metal nitride, e.g., titanium nitride, tantalum nitride, etc., or a metal, e.g., titanium, tantalum, etc.

In example embodiments, each of the first and second contact plugs 722 and 724 may be self-aligned with each of the first and second gate spacers 562 and 564 on each of the sidewall of the first and second gate structures 662 and 664.

First and second contact holes for forming the first and second contact plugs 722 and 724, respectively, which may be formed by partially removing the first insulating interlayer 680 and the insulation layer 610, may expose top surfaces of the first and second source/drain layers 602 and 604, respectively, and a metal layer may be formed on the exposed top surfaces of the first and second source/drain layers 602 and 604, and thermally treated. Unreacted portions of the metal layer may be removed to form first and second metal silicide patterns 692 and 694 on the first and second source/drain layers 602 and 604, respectively. The metal layer may be formed of, e.g., cobalt, nickel, titanium, etc.

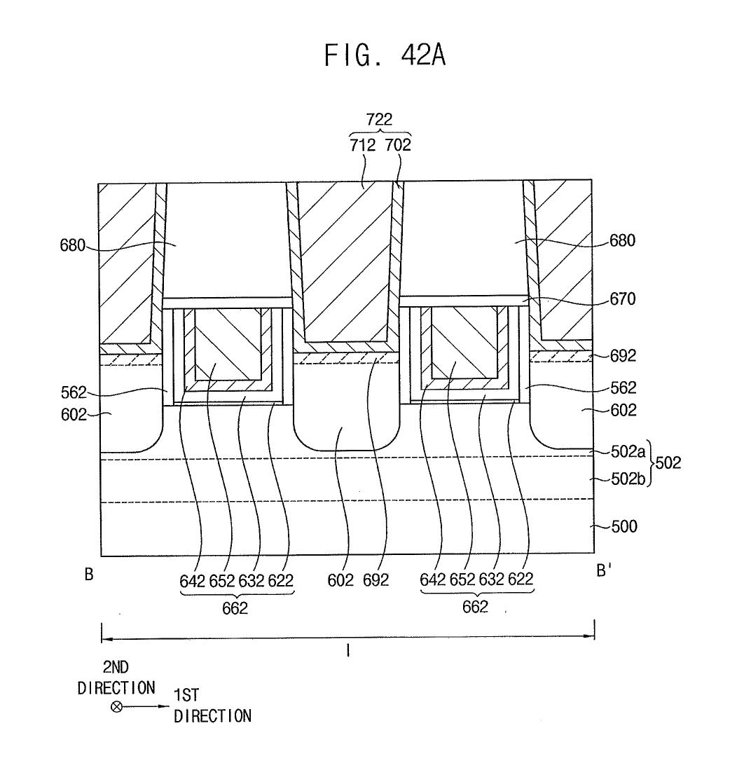

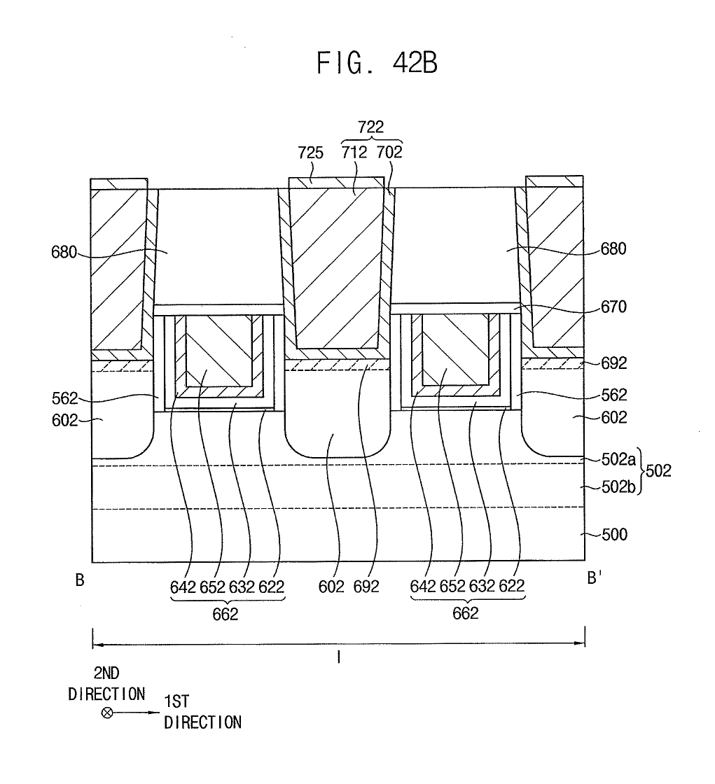

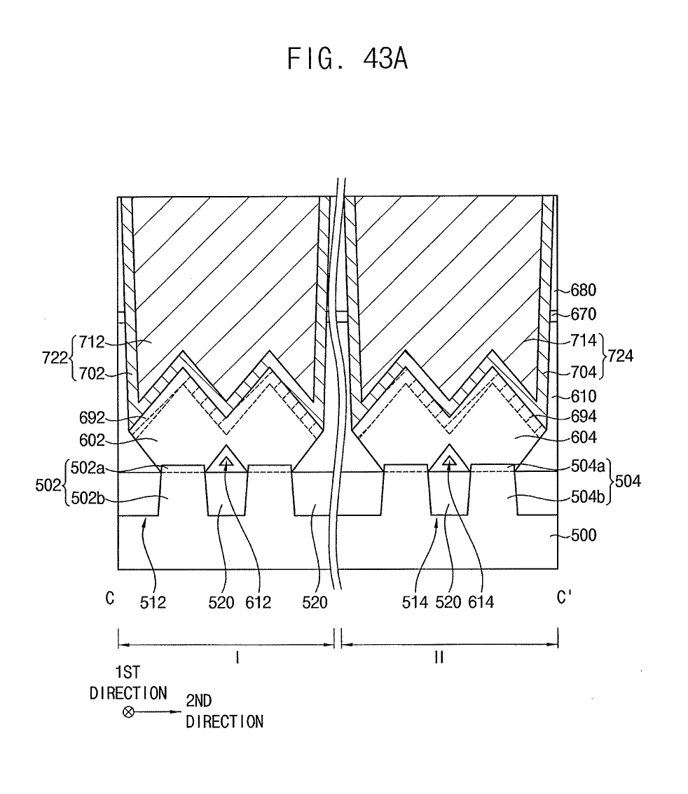

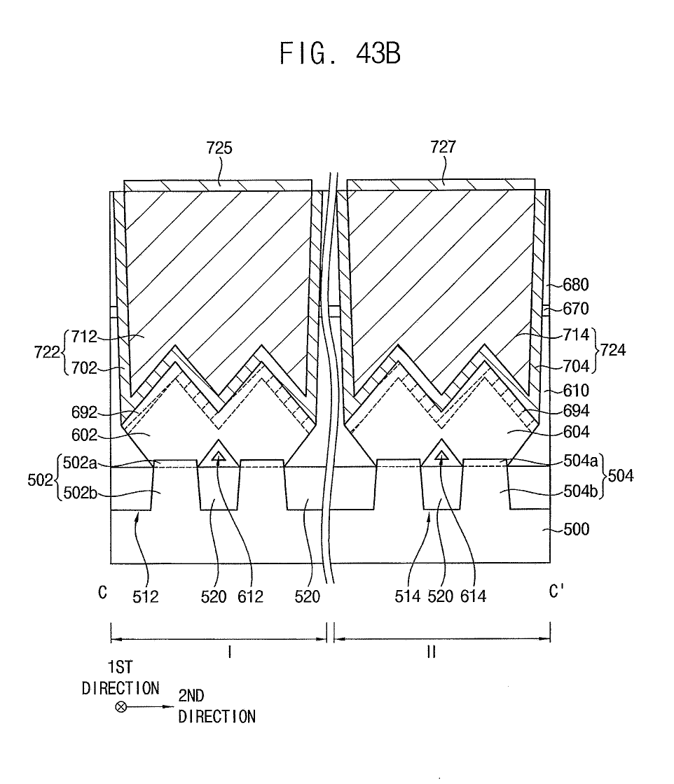

Referring to FIGS. 42B and 43B, first and second capping patterns 725 and 727 may be further formed on the first and second plugs 722 and 724, respectively.

In example embodiments, the first and second capping patterns 725 and 727 may be formed on the first and second metal patterns 712 and 714, respectively. Each of the first and second capping patterns 725 and 727 may be formed of a metal or a metal alloy, e.g., cobalt, ruthenium, tungsten, cobalt tungsten phosphorus, etc.

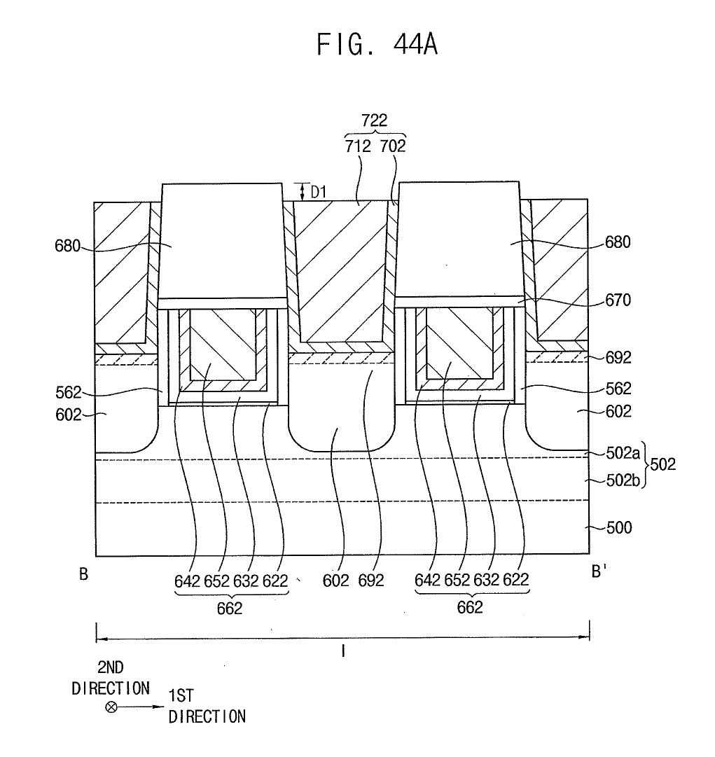

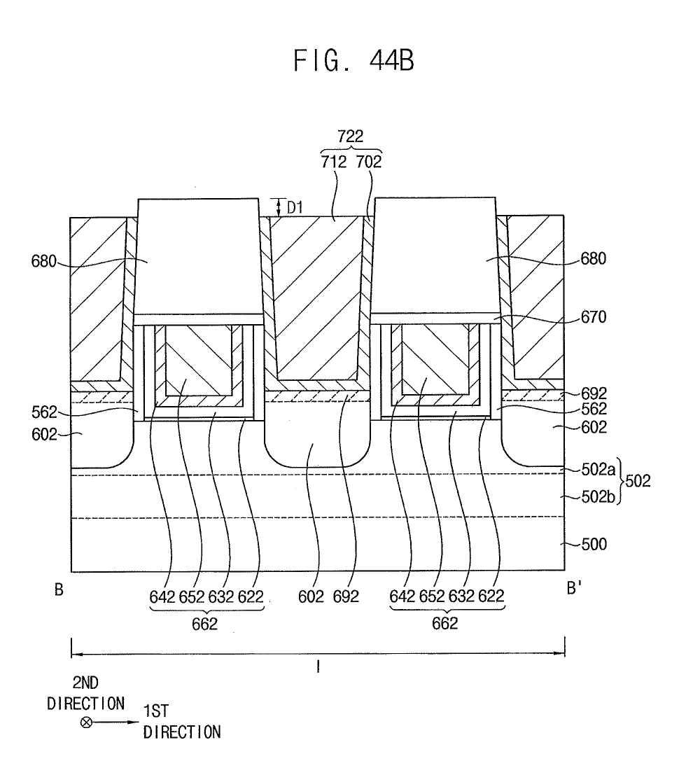

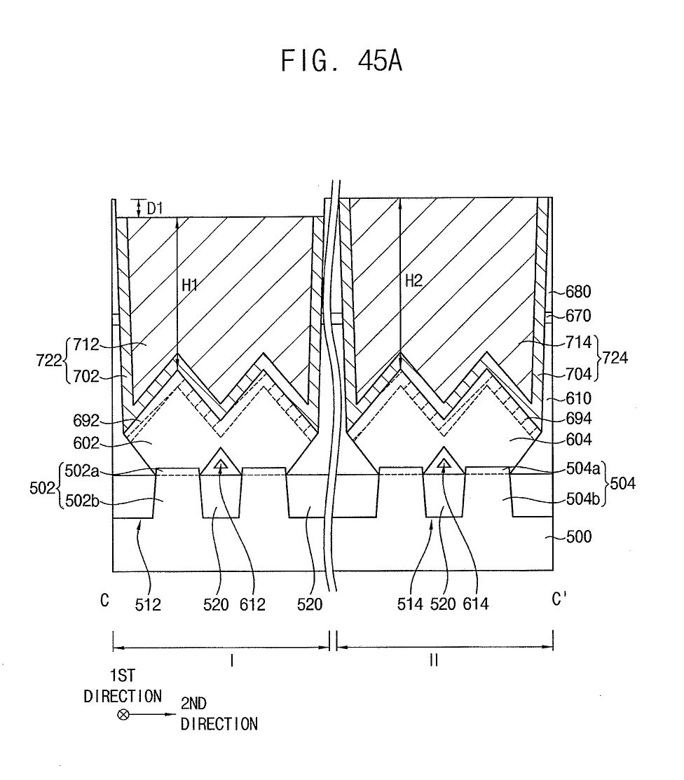

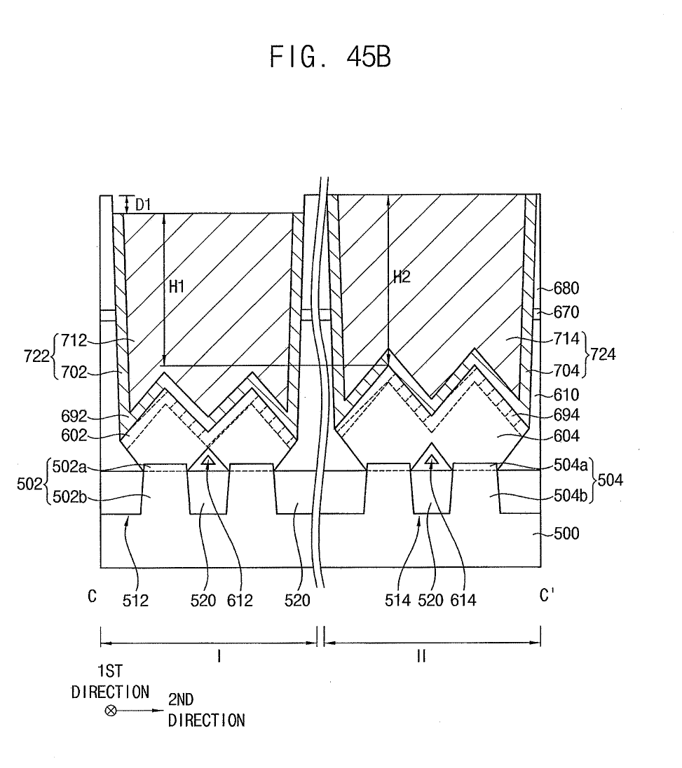

Referring to FIGS. 44A and 45A, like that of FIG. 20, a first height H1 of a top surface of the first contact plug 722 in the first region I serving as a PMOS region may be lower than a second height H2 of a top surface of the second contact plug 724 in the second region II serving as an NMOS region by a first difference D1. In example embodiments, the second height H2 may be lower than the first height H1, and the second height H2 may be equal to or more than about 80% of the first height H1. That is, the first difference D1 between the first and second heights H1 and H2 may be equal to or less than about 20% of the second height H2.

Referring to FIGS. 44B and 45B, like that of FIGS. 33B and 34B, top surfaces of the first and second source/drain layers 602 and 604 may have different heights from each other, and thus bottoms of the first and second contact plugs 722 and 724 contacting the top surfaces of the first and second source/drain layers 602 and 604, respectively, may have different heights from each other.

In the present embodiment, distances from the top surface of the second source/drain layer 604 to the top surfaces of the first and second contact plugs 722 and 724 are defined as the first and second heights H1 and H2, respectively.

The first difference D1 between the first and second heights H1 and H2 may be equal to or less than about 20% of the second height H2, and the second height H2 may be equal to or more than about 80% of the first height H1.

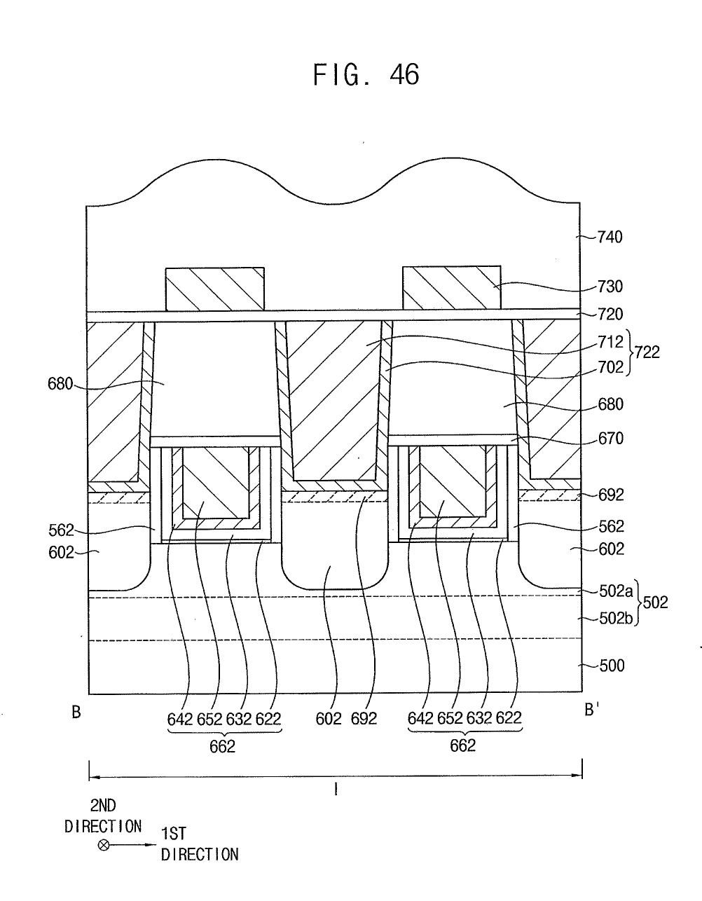

Referring to FIG. 46, an etch stop layer 720 may be formed on the first insulating interlayer 680, and the first and second contact plugs 722 and 724, and a process substantially the same as or similar to that illustrated with reference to FIG. 13 may be performed.

Thus, a resist pattern 730 may be formed on the etch stop layer 720, and a second insulating interlayer 740 may be formed on the etch stop layer 720 to cover the resist pattern 730.

The etch stop layer 720 may be formed of a nitride, e.g., silicon nitride, silicon oxynitride, silicon oxycarbonitride, etc.

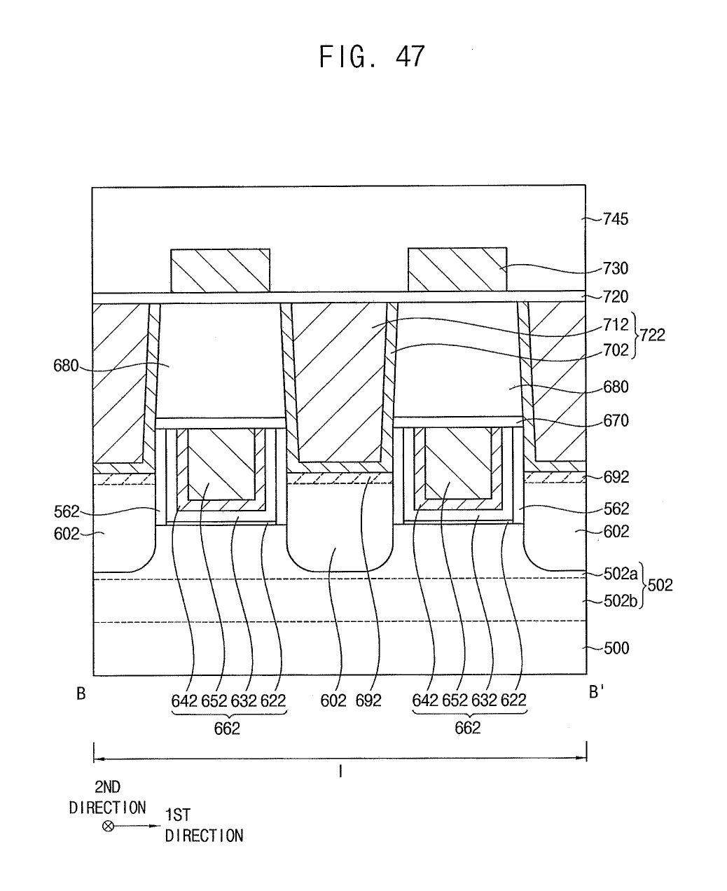

Referring to FIG. 47, processes substantially the same as or similar to those described with reference to FIGS. 14 to 16 may be performed.

Thus, the second insulating interlayer 740 may be transformed into a second insulating interlayer pattern 745.

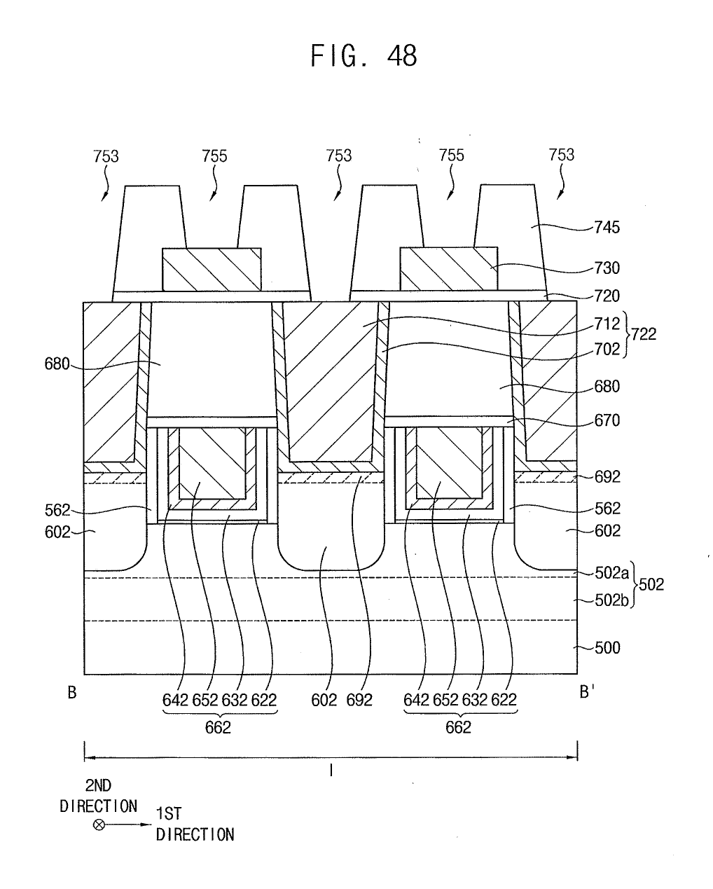

Referring to FIG. 48, the second insulating interlayer pattern 745 and the etch stop layer 720 thereunder may be partially removed to form third and fourth openings 753 and 755 exposing top surfaces of the first and second contact plugs 722 and 724 and the resist pattern 730, respectively.

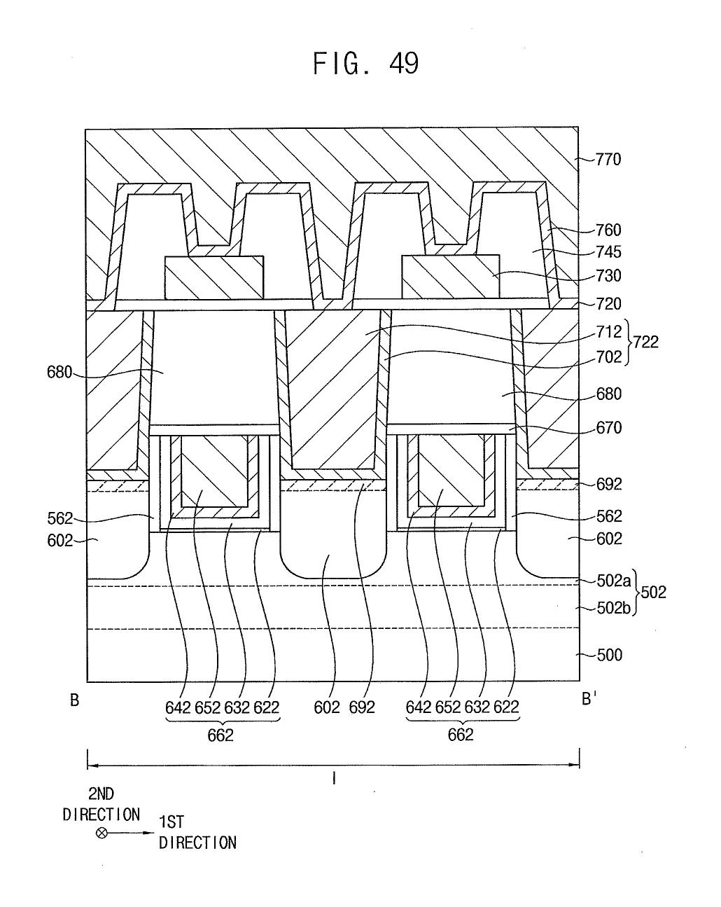

Referring to FIG. 49, a process substantially the same as or similar to that described with reference to FIG. 5 may be performed.

Thus, a barrier layer 760 may be formed on the exposed top surfaces of the first and second contact plugs 722 and 724 and the resist pattern 730, sidewalls of the third and fourth openings 753 and 755, a top surface of the second insulating interlayer pattern 745, and a metal layer 770 may be formed on the barrier layer 760 to fill the third and fourth openings 753 and 755.

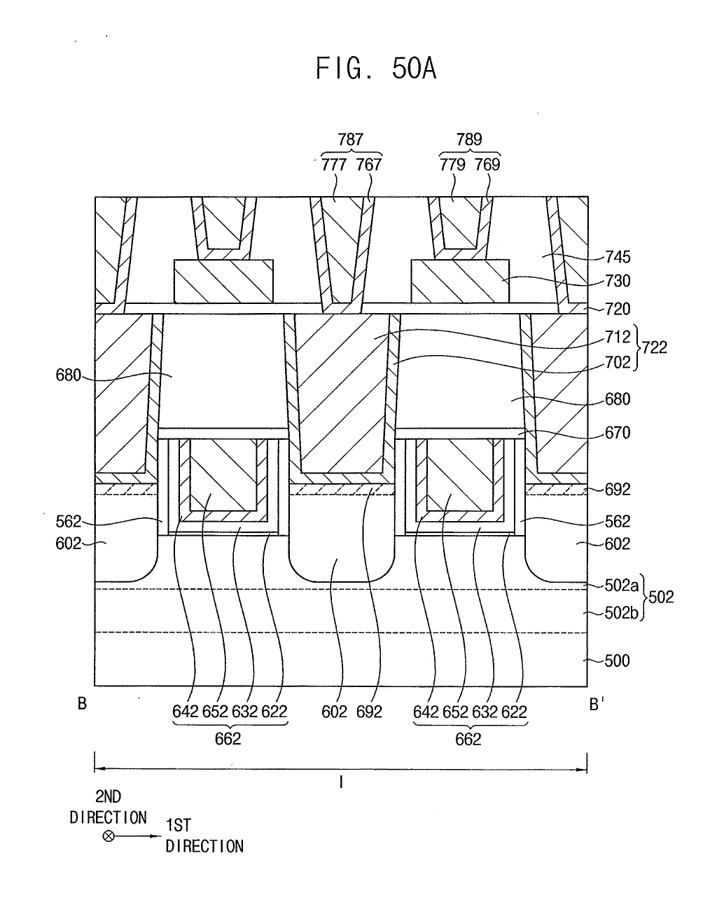

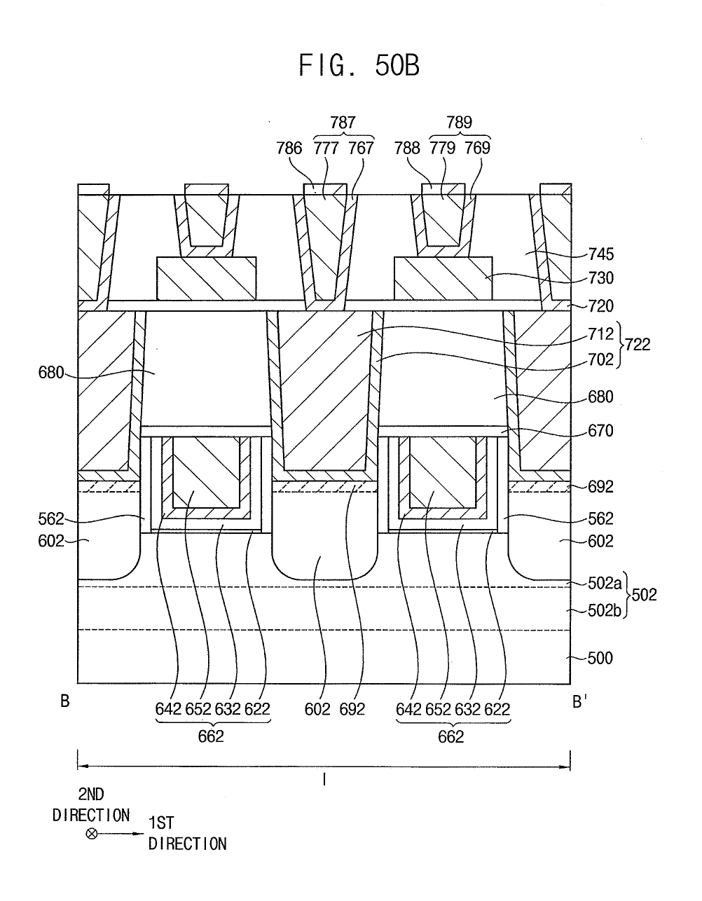

Referring to FIG. 50A, processes substantially the same as or similar to those described with reference to FIGS. 6 to 8 may be performed.

Thus, a third contact plug 787 may be formed on the top surface of one of the first and second contact plugs 722 and 724, and a fourth contact plug 789 may be formed on the top surface of the resist pattern 730. Each of the third and fourth contact plugs 787 and 789 not only formed in the NMOS region II but also formed in the PMOS region I may not have a recess thereon.

The third contact plug 787 may include a third metal pattern 777 and a third barrier pattern 767 covering a bottom and a sidewall of the third metal pattern 777, and the fourth contact plug 789 may include a fourth metal pattern 779 and a fourth barrier pattern 769 covering a bottom and a sidewall of the fourth metal pattern 779. Each of the third and fourth metal patterns 777 and 779 may be formed of a metal, e.g., tungsten, copper, aluminum, etc., and each of the third and fourth barrier patterns 767 and 769 may be formed of a metal nitride, e.g., titanium nitride, tantalum nitride, etc., or a metal, e.g., titanium, tantalum, etc.

Referring to FIG. 50B, like that of FIGS. 42B and 43B, third and fourth capping patterns 786 and 788 may be formed on the third and fourth contact plugs 787 and 789, respectively.

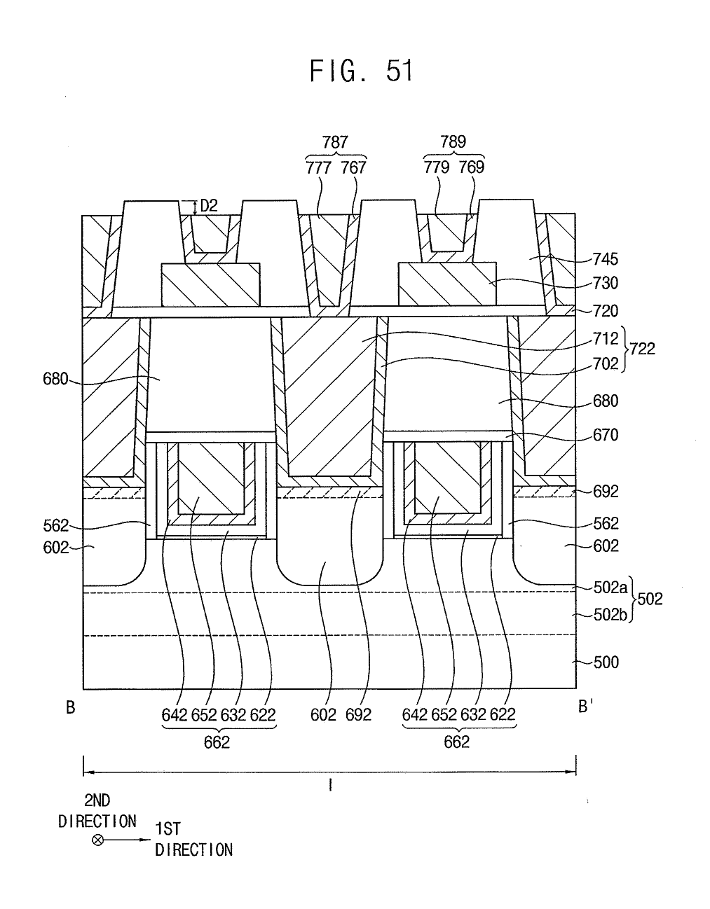

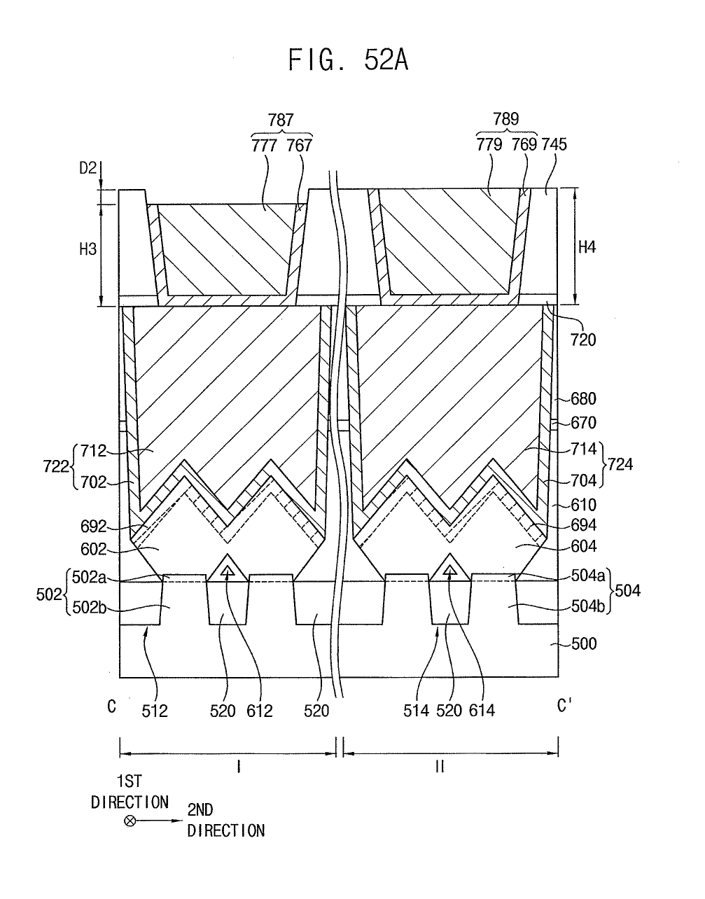

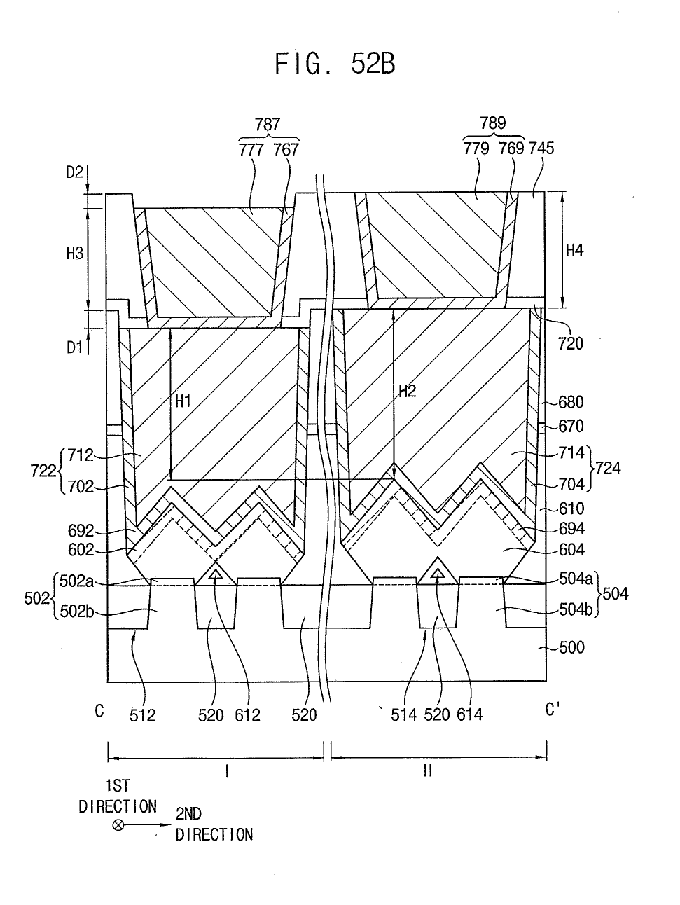

Referring to FIGS. 51 and 52A, like that of FIG. 20, top surfaces of the third and fourth contact plugs 787 and 789 in the PMOS region I may have a third height H3 lower than a fourth height H4 of top surfaces of the third and fourth contact plugs 787 and 789 in the NMOS region II by a second difference D2. In example embodiments, the second difference D2 may be equal to or less than about 20% of the fourth height H4. For example, the third height H3 may be equal to or more than about 80% of the fourth height H4.

Referring to FIG. 52B, in addition that the top surfaces of the third and fourth contact plugs 787 and 789 in the PMOS region I may have the third height H3 lower than the fourth height H4 of the top surfaces of the third and fourth contact plugs 787 and 789 in the NMOS region II, like that of FIGS. 44B and 45B, top surfaces of the first and second source/drain layers 602 and 604 may have different heights from each other. Thus, bottoms of the first and second contact plugs 722 and 724 contacting the top surfaces of the first and second source/drain layers 602 and 604, respectively, may have different heights from each other.

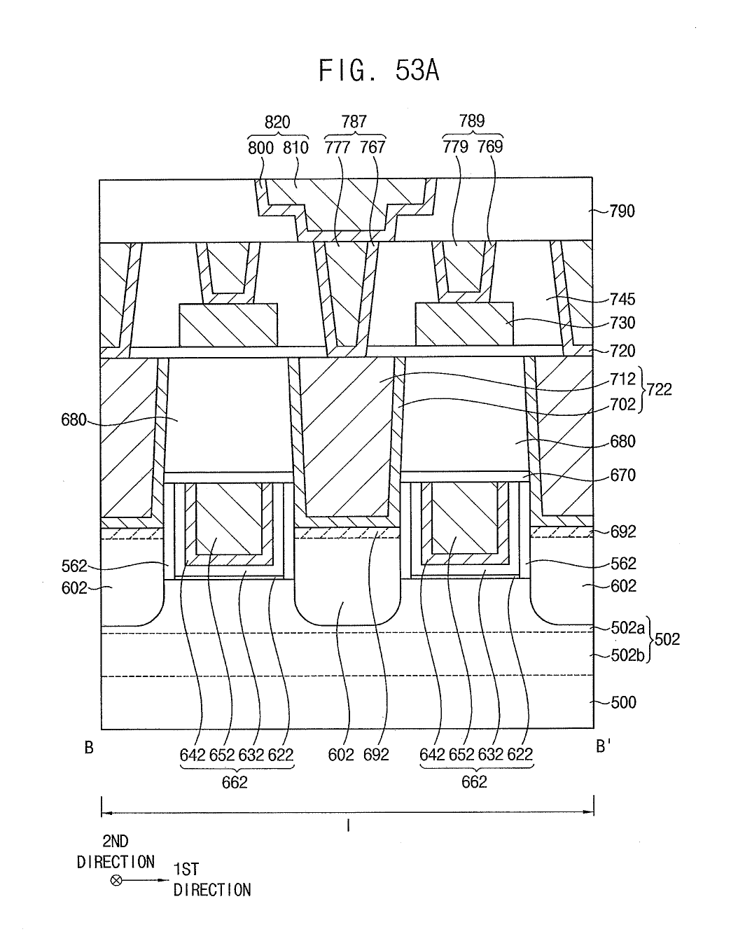

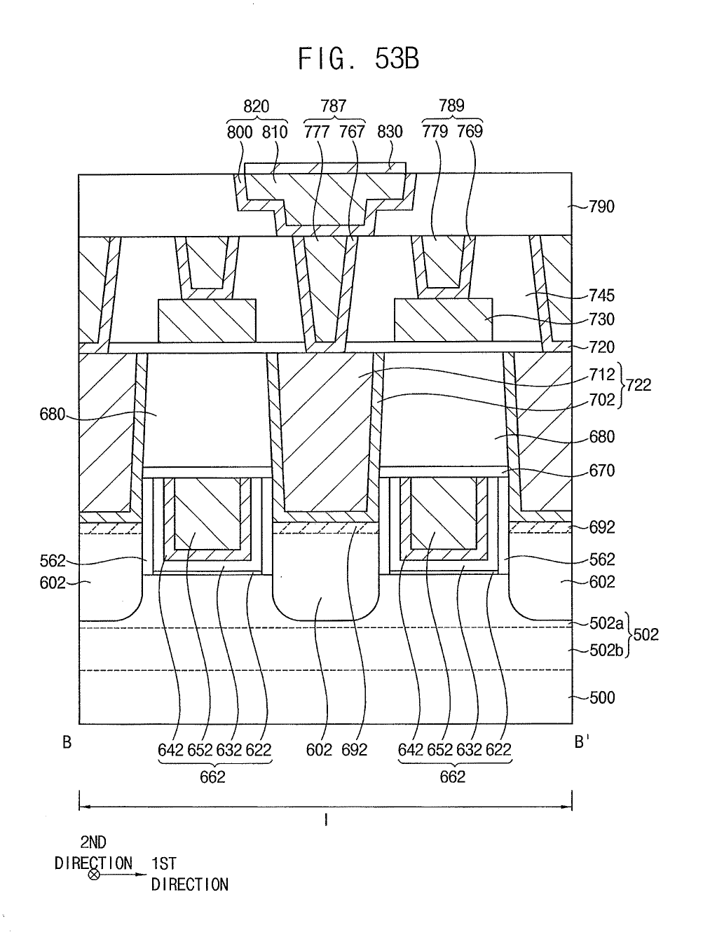

Referring to FIG. 53A, a third insulating interlayer 790 may be formed on the second insulating interlayer pattern 745 and the third and fourth contact plugs 787 and 789, and a wiring 820 may be formed through the third insulating interlayer 790 to complete the semiconductor device.

The third insulating interlayer 790 may be formed of, e.g., silicon oxide. Alternatively, the third insulating interlayer 790 may be formed of a low-k dielectric material, e.g., silicon oxide doped with carbon (SiCOH) or silicon oxide doped with fluorine (F—SiO₂), a porous silicon oxide, spin on organic polymer, or an inorganic polymer, e.g., hydrogen silsesquioxane (HSSQ), methyl silsesquioxane (MSSQ), etc.

The wiring 820 may include a fifth metal pattern 810 and a fifth barrier pattern 800 covering a bottom and a sidewall of the fifth metal pattern 810. The fifth metal pattern 810 may be formed of a metal, e.g., copper, aluminum, tungsten, etc., and the fifth barrier pattern 800 may be formed of a metal nitride, e.g., titanium nitride, tantalum nitride, etc., or a metal, e.g., titanium, tantalum, etc.

Referring to FIG. 53B, like that of FIGS. 42B and 43B, a fifth capping pattern 830 may be further formed on the wiring 820.

By way of summation and review, a CMP process may be performed by pressing a wafer onto a polishing pad and rotating the wafer while spraying slurry onto the polishing pad. After the CMP process is performed, the polishing pad may be cleaned using deionized water to remove residue in the polishing pad. During the cleaning process, a part of a tungsten contact plug may be removed to form a recess, and a semiconductor device including the tungsten contact plug may have poor reliability.

The embodiments may provide a method of forming a plug having good reliability.

The embodiments may provide a method of manufacturing a semiconductor device having good reliability.

The embodiments may provide a polishing chamber used for manufacturing a semiconductor device having good reliability.

The embodiments may provide a semiconductor device having good reliability.

In accordance with example embodiments, no recess may be formed on a metal plug that may be formed by a CMP process, and thus a semiconductor device including the metal plug may have an enhanced reliability.

The above semiconductor device and the method of manufacturing the same may be applied to various types of memory devices including contact plugs and/or wirings and methods of manufacturing the same. For example, the semiconductor device may be applied to contact plugs and/or wirings of logic devices such as central processing units (CPUs), main processing units (MPUs), or application processors (APs), or the like. Additionally, the semiconductor device may be applied to contact plugs and/or wirings of volatile memory devices such as DRAM devices or SRAM devices, or contact plugs and/or wirings of non-volatile memory devices such as flash memory devices, PRAM devices, MRAM devices, RRAM devices, or the like.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A method of forming a plug, the method comprising:
forming an opening in an insulating interlayer pattern on a substrate;
forming a metal layer on the insulating interlayer pattern to fill the opening;
performing a first CMP process during a first time period until a top surface of the insulating interlayer pattern is exposed while pressing the substrate onto a first polishing pad on a first platen to polish the metal layer;
performing a second CMP process during a second time period that is shorter than the first time period while pressing the substrate onto a second polishing pad on a second platen to polish the metal layer and the insulating interlayer pattern, so that a metal plug is formed in the insulating interlayer pattern; and
performing a first cleaning process on the second polishing pad while keeping the substrate spaced apart from the second polishing pad on the second platen.

2. The method as claimed in claim 1, wherein the metal layer is formed of tungsten, copper, or aluminum.

3. The method as claimed in claim 2, wherein the metal layer is formed of tungsten.

4. The method as claimed in claim 1, wherein the first cleaning process performed on the second polishing pad includes providing deionized water on the second polishing pad.

5. The method as claimed in claim 1, wherein:
the first cleaning process performed on the second polishing pad is performed during a third time period, and
a sum of a length of the second time period and a length of the third time period is substantially equal to a length of the first time period.

6. The method as claimed in claim 1, wherein each of the first and second CMP processes is performed using a slurry that includes abrasive particles and a strong acid solution.

7. The method as claimed in claim 6, wherein the abrasive particles include silica, alumina, or ceria.

8. The method as claimed in claim 6, wherein the strong acid solution includes hydrogen peroxide.

9. The method as claimed in claim 8, wherein, during each of the first and second CMP processes, a metal oxide layer is formed on the metal layer due to the strong acid solution.

10. The method as claimed in claim 1, further comprising, after performing the first CMP process, cleaning the first polishing pad while keeping the substrate spaced apart from the first polishing pad on the first platen.

11. The method as claimed in claim 10, wherein cleaning the first polishing pad includes providing deionized water on the first polishing pad.

12. The method as claimed in claim 10, wherein:
cleaning the first polishing pad is performed during a fourth time period, and
the method further includes, after performing the first cleaning process on the second polishing pad, performing a second cleaning process on the second polishing pad during the fourth time period while keeping the substrate spaced apart from the second polishing pad on the second platen.

13. The method as claimed in claim 1, wherein the plug has a positive potential with respect to the substrate.

14. The method as claimed in claim 1, further comprising, prior to forming the metal layer on the insulating interlayer pattern, forming a barrier layer on an inner wall of the opening and the insulating interlayer pattern,
wherein:
the metal layer and the barrier layer are polished by the first CMP process, and
the metal layer, the barrier layer, and the insulating interlayer pattern are polished by the second CMP process.

15. A method of forming a plug, the method comprising:
forming an opening in an insulating interlayer pattern on a substrate;
forming a metal layer on the insulating interlayer pattern such that the metal layer fills the opening;
performing a first CMP process while pressing the substrate onto a first polishing pad on a first platen to first polish the metal layer;
cleaning the first polishing pad while keeping the substrate spaced apart from the first polishing pad on the first platen;
performing a second CMP process while pressing the substrate onto a second polishing pad on a second platen until a top surface of the insulating interlayer pattern is exposed to second polish the metal layer;
cleaning the second polishing pad while keeping the substrate spaced apart from the second polishing pad on the second platen;
performing a third CMP process while pressing the substrate onto a third polishing pad on a third platen to polish the metal layer and the insulating interlayer pattern, so that a metal plug is formed in the insulating interlayer pattern; and
cleaning the third polishing pad while keeping the substrate spaced apart from the third polishing pad on the third platen.

16. The method as claimed in claim 15, wherein the first CMP process, the second CMP process, and the third CMP process are performed during substantially the same time.

17. The method as claimed in claim 15, further comprising, prior to forming the opening in the insulating interlayer pattern:
forming a resist pattern on the substrate;
forming an insulating interlayer on the substrate to cover the resist pattern such that a distance between the substrate and an outer surface of a portion of the insulating interlayer on the resist pattern is greater than a distance between the substrate and outer surfaces of other portions of the insulating interlayer; and
performing a fourth CMP process while pressing the substrate onto a fourth polishing pad on a fourth platen to polish the insulating interlayer such that the insulating interlayer pattern is formed from the insulating interlayer.

18. A method of manufacturing a semiconductor device, the method comprising:
forming a transistor on a substrate;
forming a first insulating interlayer on the substrate to cover the transistor;
forming a first plug through the first insulating interlayer to be electrically connected to the transistor;
forming a second insulating interlayer pattern on the first insulating interlayer and the first plug;
forming a first opening through the second insulating interlayer pattern to expose a top surface of the first plug;
forming a first metal layer on the second insulating interlayer pattern to fill the first opening;
performing a first CMP process during a first time period until a top surface of the second insulating interlayer pattern is exposed while pressing the substrate onto a first polishing pad on a first platen to polish the first metal layer;
performing a second CMP process during a second time period that is shorter than the first time period while pressing the substrate onto a second polishing pad on a second platen to polish the metal layer and the second insulating interlayer pattern, so that a second plug is formed in the second insulating interlayer pattern; and
cleaning the second polishing pad while keeping the substrate spaced apart from the second polishing pad on the second platen.

19. The method as claimed in claim 18, wherein the first metal layer is formed of tungsten.

20. The method as claimed in claim 18, wherein forming the first plug through the first insulating interlayer includes:
forming a second opening through the first insulating interlayer to expose a top surface of the substrate;
forming a second metal layer on the substrate and the first insulating interlayer to fill the second opening;
performing a third CMP process during a third time period until a top surface of the first insulating interlayer is exposed while pressing the substrate onto the first polishing pad on the first platen to polish the second metal layer;
performing a fourth CMP process during a fourth time period that is shorter than the first time period while pressing the substrate onto the second polishing pad on the second platen to polish the second metal layer and the first insulating interlayer such that the first plug is formed in the first insulating interlayer; and
cleaning the second polishing pad while keeping the substrate spaced apart from the second polishing pad on the second platen.
